(19) United States
(12) Patent Application Publication
(10) Pub. No.: US 2025/0096782 A1
(43) Pub. Date: Mar. 20, 2025

(54) SEMICONDUCTOR INTEGRATED CIRCUIT AND SEMICONDUCTOR DEVICE

(71) Applicant: Kioxia Corporation, Tokyo (JP)

(72) Inventor: Mikio SHIRAISHI, Yokohama Kanagawa (JP)

(73) Assignee: Kioxia Corporation, Tokyo (JP)

(21) Appl. No.: 18/827,999

(22) Filed: Sep. 9, 2024

(30) Foreign Application Priority Data
Sep. 19, 2023 (JP) 2023-150970

(51) Int. Cl. H03K 3/037; H03K 19/21

(52) U.S. Cl. CPC H03K 3/037; H03K 19/21

(57) ABSTRACT

According to an embodiment, a clock signal is input to clock terminals of first and second FFs. A first signal from a Q terminal of the first FF is input to a D terminal of the second FF. A first inverter performs inversion calculation on a second signal from a Q terminal of the second FF. A signal from the first inverter is input to a D terminal of the first FF. A second inverter performs inversion calculation on the first signal. (L−1) adders each calculate a different bit of a Gray code by an addition operation based on a carry signal. A circuit block generates a carry signal for a first adder based on a logical product of the first/second signals. The circuit block generates carry signals of second to (L−1)th adders based on the second signal and a signal from the second inverter.

### CROSS-REFERENCE TO RELATED APPLICATIONS

This application is based upon and claims the benefit of priority from Japanese Patent Application No. 2023-150970, filed on Sep. 19, 2023, the entire contents of which are incorporated herein by reference.

### FIELD

Embodiments described herein relate generally to a semiconductor integrated circuit and a semiconductor device.

### BACKGROUND

A Gray code counter has been known as a semiconductor integrated circuit that outputs a Gray code corresponding to a count value of a clock. The Gray code is a code that a mere one bit thereof changes with a change of one count value of a clock.

### BRIEF DESCRIPTION OF THE DRAWINGS

FIG. 1 is a diagram illustrating an example of a circuit configuration of a Gray code counter according to a first embodiment;

FIG. 2 is a timing chart illustrating an example of transition of various signals in the Gray code counter according to the first embodiment;

FIG. 3 is a truth table corresponding to the timing chart illustrated in FIG. 2;

FIG. 4 is a diagram illustrating an example of a circuit configuration of the Gray code counter according to a second embodiment;

FIG. 5 is a timing chart illustrating an example of transition of various signals in the Gray code counter according to the second embodiment;

FIG. 6 is a diagram illustrating an example of a circuit configuration of a Gray code counter according to a third embodiment;

FIG. 7 is a timing chart illustrating an example of transition of various signals in the Gray code counter according to the third embodiment;

FIG. 8 is a diagram illustrating an example of a circuit configuration of a Gray code counter according to a fourth embodiment;

FIG. 9 is a truth table of the Gray code counter according to the fourth embodiment in a case where a selection signal SEL is set to “0”;

FIG. 10 is a timing chart illustrating an example of transition of various signals in the Gray code counter according to the fourth embodiment;

FIG. 11 is a diagram illustrating an example of a circuit configuration of a Gray code counter according to a fifth embodiment;

FIG. 12 is a timing chart illustrating an example of transition of various signals in the Gray code counter according to the fifth embodiment;

FIG. 13 is a diagram illustrating an example of a circuit configuration of a Gray code counter according to a sixth embodiment;

FIG. 14 is a timing chart illustrating an example of transition of various signals in the Gray code counter according to the sixth embodiment;

FIG. 15 is a diagram illustrating an example of a circuit configuration of a Gray code counter according to a seventh embodiment;

FIG. 16 is a timing chart illustrating an example of transition of various signals in the Gray code counter according to the seventh embodiment;

FIG. 17 is a diagram illustrating an example of a circuit configuration of a Gray code counter according to an eighth embodiment;

FIG. 18 is a timing chart illustrating an example of transition of various signals in the Gray code counter according to the eighth embodiment;

FIG. 19 is a diagram illustrating an example of a configuration of a memory system according to a ninth embodiment;

FIG. 20 is a diagram illustrating an example of a partial configuration of a bridge chip according to the ninth embodiment;

FIG. 21 is a diagram illustrating an example of a configuration of a frequency counter according to the ninth embodiment; and

FIG. 22 is a timing chart illustrating an example of waveforms of various signals in the frequency counter according to the ninth embodiment.

### DETAILED DESCRIPTION

According to the present embodiment, a semiconductor integrated circuit generates an L-bit Gray code (where L is an integer larger than or equal to 3) that corresponds to a count value of a first clock signal. The semiconductor integrated circuit includes a first flip-flop, a second flip-flop, a first inverter, a second inverter, (L−1) adders, a circuit block, a first terminal, and (L−1) second terminals. The first flip-flop includes a clock terminal to which the first clock signal is configured to be input, a D terminal, and a Q terminal configured to output a first signal. The second flip-flop includes a clock terminal to which the first clock signal is configured to be input and includes a D terminal to which the first signal output from the Q terminal of the first flip-flop is configured to be input, and a Q terminal. The first inverter is configured to perform inversion calculation on a second signal output from the Q terminal of the second flip-flop, and output a signal to be input to the D terminal of the first flip-flop. The second inverter is configured to perform inversion calculation on the first signal. The (L−1) adders are each configured to calculate a different bit of the Gray code by an addition operation based on a carry signal input to the corresponding adder. The circuit block is configured to generate a carry signal to be input to a first adder of the (L−1) adders, on a basis of a calculation of a logical product of the first signal and the second signal. The circuit block is configured to generate carry signals to be individually input to a second adder to an (L−1)th adder of the (L−1) adders, on a basis of the second signal and a signal output from the second inverter. The first terminal is configured to output the second signal. The (L−1) second terminals are each configured to output a third signal output from a corresponding one of the (L−1) adders.

Hereinafter, a semiconductor integrated circuit and a semiconductor device according to embodiments will be described in detail with reference to the accompanying drawings. Note that the present disclosure is not limited by the embodiments.

### First Embodiment

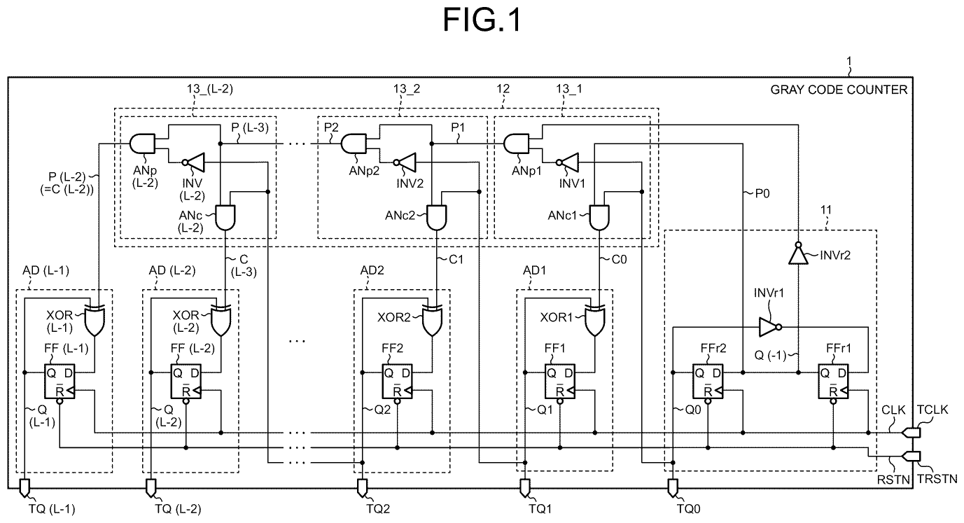

FIG. 1 is a diagram illustrating an example of a circuit configuration of a Gray code counter which is a semiconductor integrated circuit according to a first embodiment. In the following description, correspondence between a level of a signal and a logical value is assumed that an “H” state represents “1” and an “L” state represents “0”.

The Gray code counter 1 outputs a Gray code of L bits (L is an integer larger than or equal to 3) corresponding to a count value of a clock signal CLK input thereto.

The Gray code counter 1 includes a clock terminal TCLK to which the clock signal CLK is input, a reset input terminal TRSTN to which a reset signal RSTN is input, and L data output terminals TQ0 to TQ(L−1) that output different bits of the L-bit Gray code.

In this specification, the least significant bit of a Gray code is referred to as a 0-th bit, and an i-th (where i is an integer from 0 to (L−1)) bit from the least significant bit of the Gray code is referred to as an i-th bit. A data output terminal TQi outputs the i-th bit of the Gray code. A signal indicating i-th bit data of the Gray code is referred to as a data signal Qi. Hereinafter, each of the data output terminals TQ0 to TQ(L−1) may be referred to as a data output terminal TQ. The data signals Q0 to Q(L−1) may be collectively referred to as a data signal Q.

The Gray code counter 1 includes a first circuit block 11, a second circuit block 12, and (L−1) adders AD1 to AD(L−1). Hereinafter, each of the adders AD1 to AD(L−1) may be referred to as an adder AD.

A carry signal C is input to each of the adders AD from the second circuit block 12. Each of the adders AD calculates a different bit of the Gray code by an addition operation based on the carry signal C input to the corresponding adder AD and outputs, as a data signal Q, data of the bit obtained by the calculation. Hereinafter, a carry signal C input to an adder ADj (where j is an integer from 1 to (L−1)) is referred to as a carry signal C(j−1).

An adder ADj includes an XOR circuit XORj and a flip-flop FFj. The XOR circuit XORj performs an exclusive OR (in other words, XOR) operation. The flip-flop FFj is a D flip-flop that includes a Q terminal, a D terminal, a clock terminal, and a reset terminal.

The XOR circuit XORj includes two input terminals. One of the two input terminals is connected to the Q terminal of the flip-flop FFj. The other one of the two input terminals of the XOR circuit XORj is connected to the second circuit block 12, and a carry signal C(j−1) is input thereto as the carry signal C from the second circuit block 12. An output terminal of the XOR circuit XORj is connected to the D terminal of the flip-flop FFj.

Data output from the Q terminal of the flip-flop FFj is referred to as a data signal Qj. Therefore, the XOR circuit XORj inverts the data signal Qj and outputs the inverted data signal when the carry signal C is “1”, and outputs the data signal Qj without inverting the data signal Qj when the carry signal C is “0”.

The flip-flop FFj captures a signal, which is input from the XOR circuit XORj to the D terminal, at the next clock cycle (to be precise, the next rising timing of the clock signal CLK) and outputs the captured signal from the Q terminal.

Therefore, when the carry signal C(j−1) is “1”, the adder ADj performs a bit operation of adding “1” to a value represented by the current data signal Qj and outputs a signal obtained by the bit operation as the data signal Qj in the next clock cycle. When the carry signal C(j−1) is “0”, the adder ADj outputs a value represented by the current data signal Qj as the data signal Qj in the next clock cycle without changing the value of the current data signal Qj.

The Q terminal of the flip-flop FFj is connected to a data output terminal TQj of the data output terminals TQ1 to TQ(L−1). Therefore, the data output terminals TQ1 to TQ(L−1) output a set of data signals Q1 to Q(L−1) that are output from the adders AD1 to AD(L−1).

A reset signal RSTN is input to the reset terminal of the flip-flop FFj. Note that, in this example, it is assumed that the flip-flop FFj is reset when the reset signal RSTN is “0”.

The second circuit block 12 calculates carry signals C input to the adders AD1 to AD(L−1), namely, carry signals C0 to C(L−2) on the basis of reference signals input from the first circuit block 11.

The second circuit block 12 may calculate the carry signals C0 to C(L−2) by the ripple carry method or may calculate the carry signals C0 to C(L−2) by the carry look ahead method. In the example illustrated in FIG. 1, the second circuit block 12 has a configuration to calculate the carry signals C0 to C(L−2) by the ripple carry method.

The second circuit block 12 includes (L−2) element blocks 13_1 to 13_(L−2) that are connected in series. The element blocks 13_1 to 13_(L−2) may be collectively referred to as the element blocks 13.

A carry generation signal P, which is a signal used for generating the carry signals C, is propagated from the element block 13_1 to the element block 13_(L−2). Each of the element blocks 13 generates a carry signal C and a carry generation signal P to be propagated to an element block 13 in the subsequent stage on the basis of a carry generation signal P propagated thereto. A carry generation signal P generated by an element block 13_m (where m is an integer from 1 to (L−2)) is referred to as a carry generation signal Pm.

The element block 13_1 includes an AND circuit ANp1 and outputs a carry generation signal P1 from an output terminal of the AND circuit ANp1. Prior to describing of the configuration of the element block 13_1 in further detail, the configuration of the element blocks 13_2 to 13_(L−2) will be described.

The element blocks 13_2 to 13_(L−2) are similarly configured. An element block 13_k (where k is an integer from 2 to (L−2)) generates a carry signal C(k−1) and a carry generation signal Pk on the basis of a carry generation signal P(k−1) and a data signal Q(k−1).

The element block 13_k includes two AND circuits ANpk and ANck and an inverter INVk. Each of the AND circuits ANpk and ANck includes two input terminals.

A Q terminal of a flip-flop FF(k−1) included in an adder AD(k−1) is connected to a first one of the two input terminals of the AND circuit ANck, and the data signal Q(k−1) output from the Q terminal of the flip-flop FF(k−1) is input thereto. An output terminal of an element block 13_(k−1), more precisely, an output terminal of an AND circuit ANp(k−1) included in the element block 13_(k−1) is connected to a second one of the two input terminals of the AND circuit ANck, and a carry generation signal P(k−1) is input thereto. An output terminal of the AND circuit ANck is connected a second one of two input terminals of an XOR circuit XORk included in the adder ADk.

The AND circuit ANck calculates the logical product of the data signal Q(k−1) and the carry generation signal P(k−1). A signal obtained by the logical product calculation is input to the XOR circuit XORk as the carry signal C(k−1).

The Q terminal of the flip-flop FF(k−1) included in the adder AD(k−1) is connected to an input terminal of an inverter INVk, and the data signal Q(k−1) output from the Q terminal of the flip-flop FF(k−1) is input thereto. The inverter INVk performs inversion calculation on the data signal Q(k−1) and outputs a calculation result.

The output terminal of the AND circuit ANp(k−1) included in the element block 13_(k−1) is connected to a first one of the two input terminals of the AND circuit ANpk, and the carry generation signal P(k−1) output from the AND circuit ANp(k−1) is input thereto. An output terminal of the inverter INVk is connected to a second one of the two input terminals of the AND circuit ANpk, and the data signal Q(k−1) inverted by the inverter INVk is input thereto. The AND circuit ANpk calculates the logical product of the carry generation signal P(k−1) and the inverted data signal Q(k−1). A signal obtained by the logical product calculation is output from the element block 13_k as the carry generation signal Pk.

In this manner, the carry generation signal P is propagated from the element block 13_2 to the element block 13_(L−2). Each element block 13_k generates the carry signal C(k−1) on the basis of the carry generation signal P(k−1) propagated from the element block 13_(k−1) in the previous stage and the data signal Q(k−1) output from the adder AD(k−1). Moreover, each element block 13_k newly generates the carry generation signal Pk on the basis of the carry generation signal P(k−1) and the data signal Q(k−1). The generated carry generation signal Pk is output to an element block 13_(k+1) in the subsequent stage.

In the element block 13_(L−2) that is the element block 13 in the last stage of the element blocks 13_2 to 13_(L−2), an output terminal of an AND circuit ANp(L−2) is connected to a second one of two input terminals of an XOR circuit XOR(L−1) included in the adder AD(L−1). A carry generation signal P(L−2) output from the output terminal of the AND circuit ANp(L−2) is input to the XOR circuit XOR(L−1) as a carry signal C(L−2).

The first circuit block 11 generates reference signals to be supplied to the second circuit block 12 on the basis of the clock signal CLK.

Hereinafter, technology to be compared with the embodiment will be described. The technology to be compared with the embodiment is referred to as a comparative example. According to the comparative example, a circuit block for generating reference signals includes a D flip-flop. The D flip-flop included in the circuit block for generating the reference signals is referred to as a reference flip-flop.

In the comparative example, a clock signal is input to a clock terminal of the reference flip-flop, and data held by the reference flip-flop is inverted for every clock cycle. The circuit block generates the reference signals on the basis of the data held by the reference flip-flop and is inverted for every clock cycle.

Since the Gray code changes only one bit in every clock cycle, power consumption caused by inversion of data in flip-flops (for example, flip-flops FF1 to FF(L−1) in the configuration illustrated in FIG. 1) that hold respective bits of the Gray code is small. As in the comparative example, in the case where the flip-flop in which data is inverted for every clock cycle for generating the reference signals is provided as the reference flip-flop, the power consumption caused by the inversion of the data in the reference flip-flop is significantly larger than the power consumption caused by inversion of data in flip-flops holding the respective bits of the Gray code, and the power consumption of the Gray code counter increases.

Therefore, in the first embodiment, the first circuit block 11 is configured such that the data held by the reference flip-flop is inverted is less frequency than in the comparative example. By reducing the frequency of inversion of the data held by the reference flip-flop, the power consumption caused by inversion of the data of the reference flip-flop is reduced, and accordingly, the power consumption of the Gray code counter 1 is reduced.

Specifically, the first circuit block 11 includes two reference flip-flops FFr1 and FFr2 and two inverters INVr1 and INVr2. Each of the reference flip-flops FFr1 and FFr2 is a D flip-flop including a Q terminal, a D terminal, a clock terminal, and a reset terminal.

The clock signal CLK is input to the clock terminals of the reference flip-flops FFr1 and FFr2, and the reset signal RSTN is input to the reset terminals of the reference flip-flops FFr1 and FFr2. Note that, in this example, the reference flip-flops FFr1 and FFr2 are reset when the reset signal RSTN is “0”.

The Q terminal of the reference flip-flop FFr1 is connected to the D terminal of the reference flip-flop FFr2, and a signal output from the Q terminal of the reference flip-flop FFr1 is input thereto. The Q terminal of the reference flip-flop FFr2 is connected to an input terminal of the inverter INVr1. The inverter INVr1 performs inversion calculation on a signal output from the Q terminal of the reference flip-flop FFr2. An output terminal of the inverter INVr1 is connected to the D terminal of the reference flip-flop FFr1. A signal output from the inverter INVr1 is input to the D terminal of the reference flip-flop FFr1.

Therefore, the data held by the reference flip-flops FFr1 and FFr2 is inverted at a time interval twice the clock cycle of the clock signal CLK. The inversion of the data held by the reference flip-flops FFr1 and FFr2 is made less frequent than the frequency of inversion of the data held by the reference flip-flop according to the comparative example, and thus the power consumption of the Gray code counter 1 is reduced as compared with that of the comparative example.

The signal output from the Q terminal of the reference flip-flop FFr2 is referred to as a data signal Q0. The Q terminal of the reference flip-flop FFr2 is connected to a data terminal TQ0. The data terminal TQ0 outputs the data signal Q0 output from the Q terminal of the reference flip-flop FFr2.

The signal output from the Q terminal of the reference flip-flop FFr1 is referred to as a data signal Q(−1) for the sake of convenience. Note that the data signal Q(−1) is not output from the Gray code counter 1 to the outside.

The Q terminal of the reference flip-flop FFr1 is connected to an input terminal of the inverter INVr2. The inverter INVr2 performs inversion calculation on the data signal Q(−1) output from the Q terminal of the reference flip-flop FFr1.

The signal output from the Q terminal of the reference flip-flop FFr2 (namely, the data signal Q0), the signal output from the Q terminal of the reference flip-flop FFr1 (namely, the data signal Q(−1)), and a signal output from the output terminal of the inverter INVr2 (namely, the signal obtained by inverting the data signal Q(−1)) are input as reference signals to the second circuit block 12.

The signal output from the Q terminal of the reference flip-flop FFr1 and input to the second circuit block 12 is referred to as a carry generation signal P0 for convenience. Thus, the data signal Q(−1) is input to the second circuit block 12 as the carry generation signal P0.

In the second circuit block 12, the element block 131 generates the carry signal C0 and the carry generation signal P1 on the basis of the data signal Q0, the signal obtained by inverting the data signal Q(−1), and the carry generation signal P0. As a configuration for this, the element block 13_1 includes two AND circuits ANp1 and ANc1 and an inverter INV1.

The Q terminal of the reference flip-flop FFr2 included in the first circuit block 11 is connected to a first one of two input terminals of the AND circuit ANc1, and the data signal Q0 output from the Q terminal of the reference flip-flop FFr2 is input thereto. The Q terminal of the reference flip-flop FFr1 is connected to a second one of two input terminals of the AND circuit ANc1, and the carry generation signal P0 output from the Q terminal of the reference flip-flop FFr1 is input thereto.

An output terminal of the AND circuit ANc1 is connected a second one of two input terminals of an XOR circuit XOR1 included in the adder AD1. The AND circuit ANc1 calculates the logical product of the data signal Q0 and the carry generation signal P0. A signal obtained by the logical product calculation is input to the XOR circuit XOR1 included in the adder AD1 as the carry signal C0.

The Q terminal of the reference flip-flop FFr2 included in the first circuit block 11 is connected to an input terminal of the inverter INV1, and the data signal Q0 output from the Q terminal of the reference flip-flop FFr2 is input thereto. The inverter INV1 performs inversion calculation on the data signal Q0.

The output terminal of the inverter INVr2 included in the first circuit block 11 is connected to a first one of two input terminals of the AND circuit ANp1, and the data signal Q(−1) inverted by the inverter INVr2 is input thereto. An output terminal of the inverter INV1 is connected to a second one of the two input terminals of the AND circuit ANp1, and the data signal Q0 inverted by the inverter INV1 is input thereto. The AND circuit ANp1 calculates the logical product of the inverted data signal Q(−1) and the inverted data signal Q0. A signal obtained by the logical product calculation is output from the element block 13_1 as the carry generation signal P1.

Note that, in the example illustrated in FIG. 1, the second circuit block 12 calculates the carry signals C0 to C(L−2) by the ripple carry method. As described above, the second circuit block 12 may be configured to calculate the carry signals C0 to C(L−2) by the carry look ahead method. In a case where the carry look head method is applied, the second circuit block 12 includes, for example, an arithmetic circuit that collectively calculates carry signals C1 to C(L−2) on the basis of the carry generation signal P1 instead of the element block 13_2 to 13_(L−2).

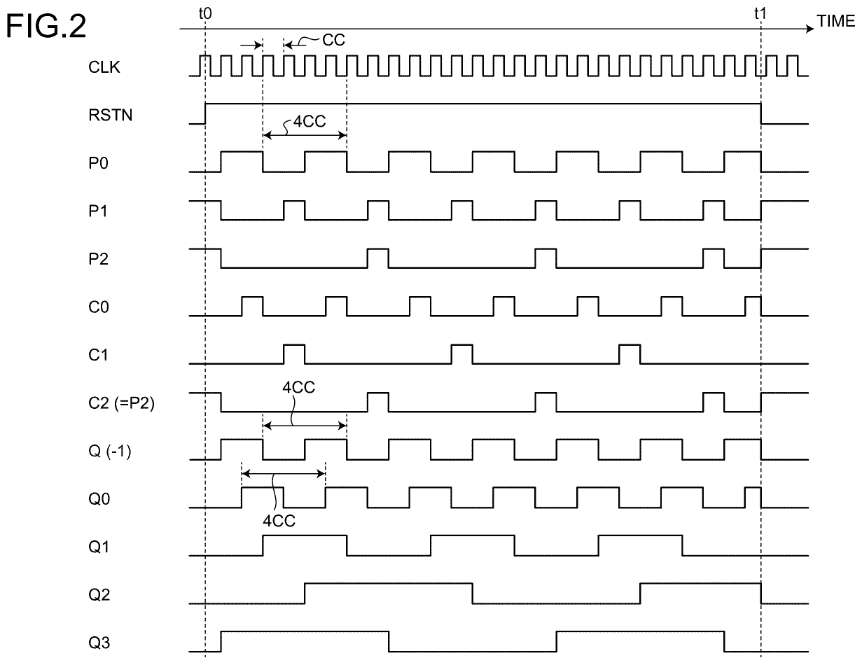

FIG. 2 is a timing chart illustrating an example of transition of various signals in the Gray code counter 1 according to the first embodiment. Note that, in this drawing, L is assumed to be “4” to facilitate understanding.

In a reset state caused by the reset signal RSTN (immediately before timing t0 in FIG. 2), the carry generation signal P0, the carry signals C0 and C1, and the data signal Q indicate “0”, and the carry generation signals P1 and P2 and the carry signal C2 indicate “1”.

Then, when the reset state by the reset signal RSTN is canceled (timing t0), the data signal Q(−1) and the carry generation signal P0, which are output from the Q terminal of the reference flip-flop FFr1, and the data signal Q0 output from the Q terminal of the reference flip-flop FFr2 transition in a waveform obtained by dividing the frequency of the clock signal CLK by four. When the clock cycle of the clock signal CLK is denoted as CC, data held by the reference flip-flops FFr1 and FFr2 periodically changes in the cycle of 4CC.

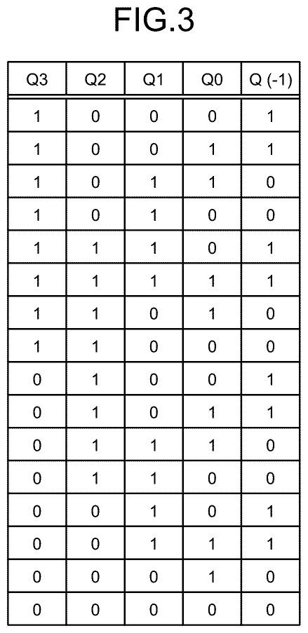

FIG. 3 is a truth table corresponding to the timing chart illustrated in FIG. 2. A four-bit Gray code Q0-Q3 is sequentially counted in a direction from the top to the bottom in the truth table illustrated in FIG. 3 for each clock cycle.

A data signal Q3 indicating the value of the most significant bit of the four-bit Gray code Q0-Q3 is “1” in the first half of the count cycle and “0” in the second half of the count cycle. The Gray code counter 1 operates as a counter whose counting direction is in a downward direction, namely, a down counter.

Moreover, in the four-bit Gray code Q0-Q3, one of the bits change in every clock cycle, and the data signal Q(−1) that is the source of generation of data of the four-bit Gray code Q0-Q3 is inverted in every two clock cycles.

As described above, the Gray code counter 1 according to the first embodiment includes the reference flip-flop FFr1, the reference flip-flop FFr2, the inverter INVr1, the inverter INVr2, the (L−1) adders AD1 to AD(L−1), the second circuit block 12, and the data output terminals TQ0 to TQ(L−1). The clock signal CLK is input to the clock terminal of the reference flip-flop FFr1 and the clock terminal of the reference flip-flop FFr2. The data signal Q(−1) output from the Q terminal of the reference flip-flop FFr1 is input to the D terminal of the reference flip-flop FFr2. The inverter INVr1 performs inversion calculation on the data signal Q0 output from the Q terminal of the reference flip-flop FFr2. The signal output from the inverter INVr1 is input to the D terminal of the reference flip-flop FFr1. The inverter INVr2 performs inversion calculation on the data signal Q(−1). Each of the (L−1) adders AD1 to AD(L−1) calculates a different bit of the Gray code by an addition operation based on a carry signal C input thereto. The second circuit block 12 generates the carry signal C0 input to the adder AD1 of the (L−1) adders AD1 to AD(L−1) by calculating the logical product of the data signal Q(−1) and the data signal Q0. The second circuit block 12 generates the carry signals C1 to C(L−2) input to the adders AD2 to AD(L−1), respectively, on the basis of the data signal Q0 and the inverted data signal Q(−1) output from the inverter INVr2.

Therefore, it is possible to reduce a inversion frequency at which the data held by the reference flip-flops (for example, the reference flip-flops FFr1 and FFr2) necessary for the calculation of the reference signals is inverted, and accordingly, the power consumption of the Gray code counter 1 can be reduced. The Gray code counter 1 can operate as the down counter. Thus, the Gray code is suitably generated.

Moreover, according to the above-described first embodiment, each adder AD (denoted as an adder ADj) includes the flip-flop FFj and the XOR circuit XORj. The XOR circuit XORj inputs, to the D terminal of the flip-flop FFj, a signal obtained by the exclusive OR of a signal output from the Q terminal of the flip-flop FFj, namely, a signal Qj, and a carry signal C(j−1).

Therefore, each of the adders AD can perform an addition operation based on a carry signal C input thereto.

### Second Embodiment

In a Gray code counter with a regular structure, specifically, a structure in which circuit blocks such as the element blocks 13 and the adders AD are regularly arranged like the Gray code counter 1 of the first embodiment, there is a possibility that the counting direction is inverted when a soft error occurs due to high-energy particles or electromagnetic waves.

For example, in the Gray code counter 1 of the first embodiment, some of or all the stored contents in the flip-flops FFr1, FFr2, and FF1 to FF(L−1) may be rewritten by the soft error. By such rewriting, the counting direction changes from the downward direction to the upward direction when the Gray code counter 1 enters an illegal state, namely, a state where the set of values of the data signals Q(−1) to Q(L−1) takes a set of values not included in a truth table (for example, the truth table illustrated in FIG. 3).

In a second embodiment, a Gray code counter capable of returning from the illegal state will be described.

The Gray code counter according to the second embodiment is denoted as a Gray code counter 1a. In the description of the second embodiment, the same components as those of the first embodiment will not be described or will be briefly described.

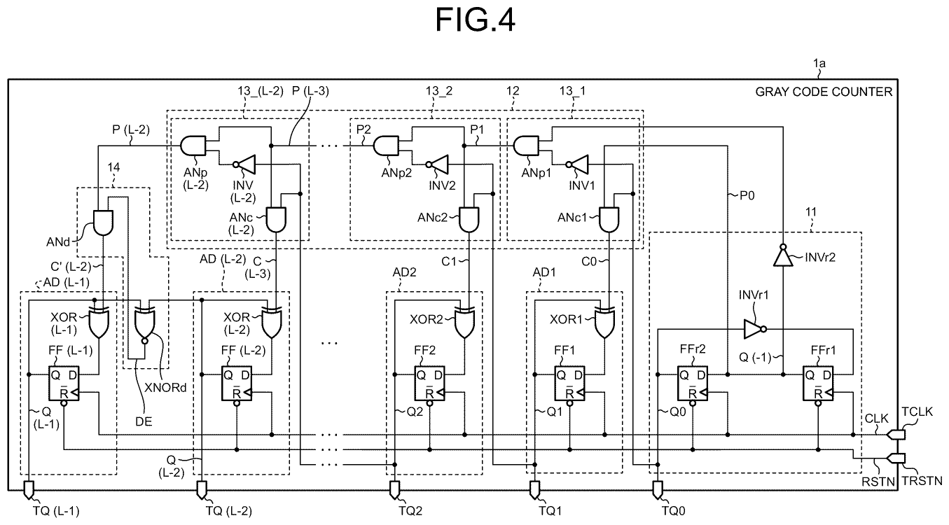

FIG. 4 is a diagram illustrating an example of a circuit configuration of the Gray code counter 1a according to the second embodiment. The circuit configuration of the Gray code counter 1a is different from the circuit configuration of the Gray code counter 1 of the first embodiment in that, a return circuit 14 is added.

The return circuit 14 disables the carry signal C input to the adder AD(L−1) depending on the values of the data signals Q(L−1) and Q(L−2), which are the values of the most significant two bits of the Gray code. Note that the disabling of the carry signal C means to prohibit the carry signal C from changing. Disabling the carry signal C can also be rephrased as masking the carry signal C.

In counting in the downward direction, the carry generation signal P(L−2) used as the carry signal C(L−2) changes from “0” to “1” only at timing when a value of the data signal Q(L−1) is equal to a value of the data signal Q(L−2). For example, in FIG. 2, the carry generation signal P2 changes from “0” to “1” only when data signal Q3 is equal to data signal Q2. On the other hand, in counting in the upward direction, the carry generation signal P(L−2) changes from “0” to “1” only at timing when the value of the data signal Q(L−1) and the value of the data signal Q(L−2) are different.

Therefore, the return circuit 14 inputs the carry generation signal P(L−2) to the adder AD(L−1) as the carry signal C only when the value of the data signal Q(L−1) is equal to the value of the data signal Q(L−2). In a case where the value of the data signal Q(L−1) is not equal to the value of the data signal Q(L−2), the return circuit 14 prevents the carry signal C for the adder AD(L−2) from changing with a change of the carry generation signal P(L−1). In this case, the return circuit 14 disables the carry signal C input to the adder AD(L−1).

Hereinafter, the carry signal C input from the return circuit 14 to the adder AD(L−1) is referred to as a carry signal C′(L−2).

The return circuit 14 includes an XNOR circuit XNORd and an AND circuit ANd.

The XNOR circuit XNORd includes two input terminals, and one of the two input terminals is connected to the Q terminal of the flip-flop FF(L−1) included in the adder AD(L−1). The other one of the two input terminals of the XNOR circuit XNORd is connected to the Q terminal of the flip-flop FF(L−2) included in the adder AD(L−2). The XNOR circuit XNORd calculates the exclusive OR of the data signal Q(L−1) output from the Q terminal of the flip-flop FF(L−1) and the data signal Q(L−2) output from the Q terminal of the flip-flop FF(L−2). Then, the XNOR circuit XNORd performs inversion calculation on a signal obtained by the exclusive OR calculation.

Hereinafter, a signal output from the XNOR circuit XNORd is referred to as a disable signal DE.

The output terminal of the AND circuit ANp(L−2) included in the element block 13_(L−2) is connected to a first one of two input terminals of the AND circuit ANd, and the carry generation signal P(L−2) output from the AND circuit ANp(L−2) is input thereto. An output terminal of the XNOR circuit XNORd is connected to a second one of the two input terminals of the AND circuit ANd, and the disable signal DE output from the XNOR circuit XNORd is input thereto. The AND circuit ANd calculates the logical product of the carry generation signal P(L−2) and the disable signal DE.

An output terminal of the AND circuit ANd is connected to the adder AD(L−1). A signal output from the AND circuit ANd is input to the adder AD(L−1) as the carry signal C′(L−2).

In a case where the value of the data signal Q(L−1) is equal to the value of the data signal Q(L−2), the disable signal DE is “1”, and the carry signal C′(L−2) is not disabled. In a case where the value of the data signal Q(L−1) and the value of the data signal Q(L−2) are different from each other, the disable signal DE is “0”, and accordingly, the carry signal C′(L−2) is disabled.

The XOR circuit XOR(L−1) included in the adder AD(L−1) calculates the exclusive OR of the carry signal C′(L−2) output from the AND circuit ANd and the data signal Q(L−1) output from the Q terminal of the flip-flop FF(L−1) included in the adder AD(L−1).

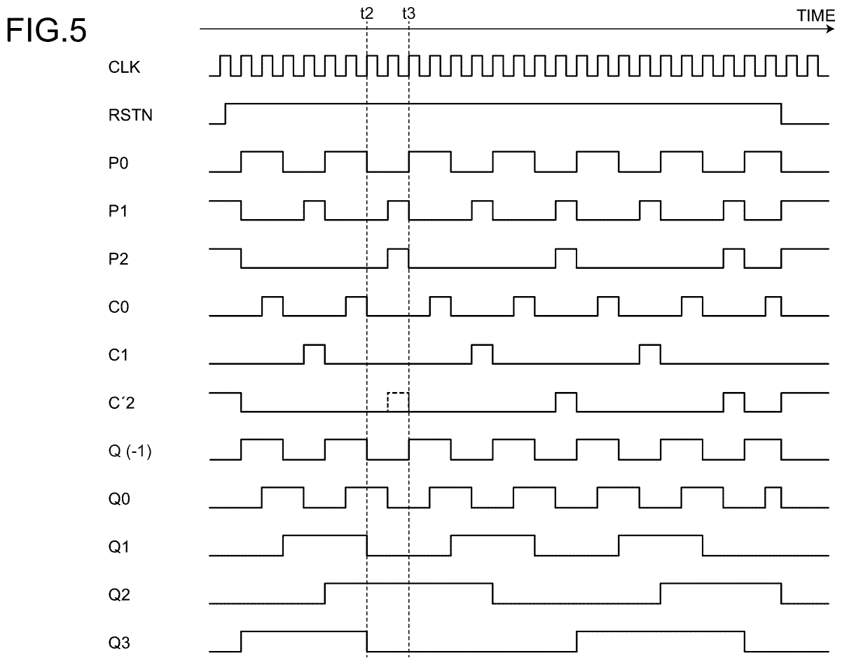

FIG. 5 is a timing chart illustrating an example of transition of various signals in the Gray code counter 1a according to the second embodiment. Also in this drawing, L is assumed to be “4” to facilitate understanding.

In the example illustrated in FIG. 5, during the counting in the downward direction, the value of the data signal Q3 changes due to a soft error, and the counting direction changes to the upward direction (timing t2).

After timing t2, the value of the data signal Q3 and the value of the data signal Q2 are different from each other. Therefore, a change from “0” to “1” of the carry signal C′2 due to a change from “0” to “1” of the carry generation signal P2 is suppressed. In short, the carry signal C′2 is disabled. This prevents the data signal Q3 from changing from “0” to “1”. After timing t3, each signal changes in a waveform similar to that of the counting operation in the downward direction illustrated in FIG. 2. The counting direction is corrected from the upward direction to the downward direction.

As described above, according to the second embodiment, even when the Gray code counter 1a enters the illegal state, it is possible to return from the illegal state. Thus, the Gray code is suitably generated.

### Third Embodiment

In a third embodiment, description will be given on a Gray code counter capable of externally outputting a notification of return from the illegal state when the return from the illegal state is performed.

The Gray code counter according to the third embodiment is referred to as a Gray code counter 1b. In the description of the third embodiment, the same components as those of the second embodiment will not be described or will be briefly described.

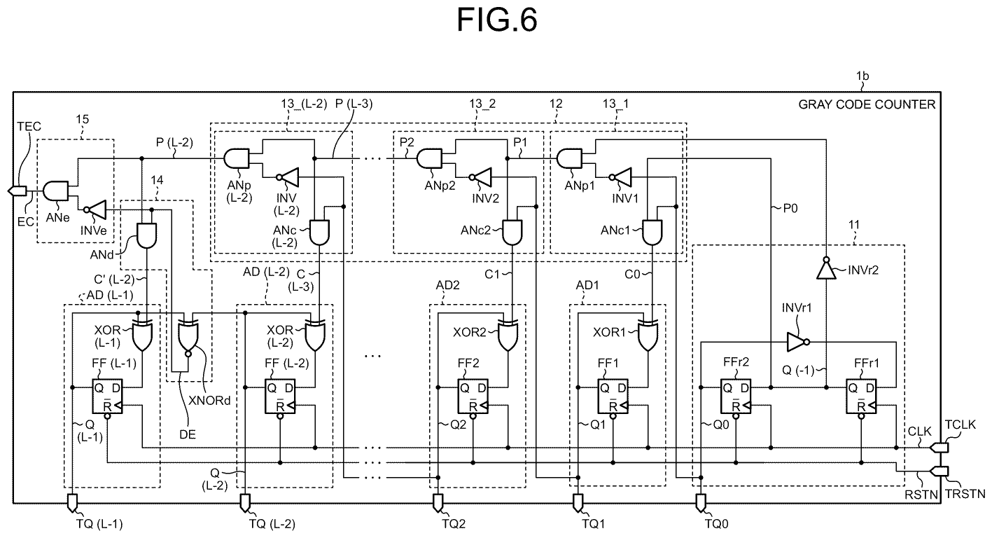

FIG. 6 is a diagram illustrating an example of a circuit configuration of the Gray code counter 1b according to the third embodiment. The circuit configuration of the Gray code counter 1b is different from the circuit configuration of the Gray code counter 1a of the second embodiment in that, a status generation circuit 15 and a status signal output terminal TEC are added.

The status generation circuit 15 includes an inverter INVe and an AND circuit ANe.

The output terminal of the XNOR circuit XNORd is connected to an input terminal of the inverter INVe, and the disable signal DE output from the XNOR circuit XNORd is input thereto. The inverter INVe performs inversion calculation on the disable signal DE.

The output terminal of the AND circuit ANp(L−2) included in the element block 13_(L−2) is connected to a first one of two input terminals of the AND circuit ANe, and the carry generation signal P(L−2) output from the AND circuit ANp(L−2) is input thereto. An output terminal of the inverter INVe is connected to a second one of the input terminals of the AND circuit ANe, and the inverted disable signal DE is input thereto. The AND circuit ANe calculates the logical product of the carry generation signal P(L−2) and the inverted disable signal DE.

In a case where the carry signal C′(L−2) is not disabled (in a case where the disable signal DE is “1”), the AND circuit ANe suppresses output of the carry generation signal P(L−2) input thereto. In a case where the carry signal C′(L−2) is disabled (in a case where the disable signal DE is “0”), the AND circuit ANe outputs the carry generation signal P(L−2) input thereto.

Therefore, when the carry generation signal P(L−2) changes from “0” to “1” in the state where the carry signal C′(L−2) is disabled, the change is directly output from the AND circuit ANe. Specifically, the AND circuit ANe outputs “1” in response to the return from the illegal state.

An output terminal of the AND circuit ANe is connected to the status signal output terminal TEC. A signal output from the AND circuit ANe is output from the status signal output terminal TEC to the outside as a status signal EC indicating whether or not return from the illegal state has been performed.

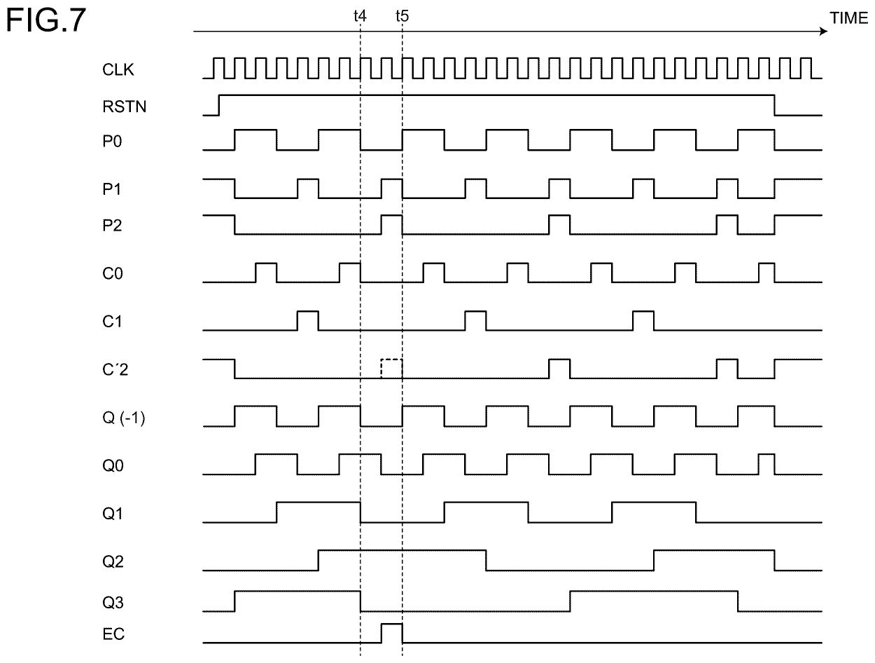

FIG. 7 is a timing chart illustrating an example of transition of various signals in the Gray code counter 1b according to the third embodiment. Also in this drawing, L is assumed to be “4” to facilitate understanding.

In the example illustrated in FIG. 7, during the counting in the downward direction, the value of the data signal Q3 changes due to a soft error, and the counting direction changes to the upward direction (timing t4).

After timing t4, the change from “0” to “1” of the carry signal C′2 due to the change from “0” to “1” of the carry generation signal P2 is suppressed, and accordingly, the counting direction is corrected from the upward direction to the downward direction.

When the change from “0” to “1” of the carry signal C′2 due to the change from “0” to “1” of the carry generation signal P2 is suppressed, the status signal EC changes from “0” to “1” as the carry generation signal P2 changes from “0” to “1”. The status signal EC changes from “0” to “1” and thereafter returns from “1” to “0” at the next rising edge of the clock CLK (timing t5).

Therefore, the notification that the counting direction has been corrected from the upward direction to the downward direction, in other words, the notification that return from the illegal state has been performed is output to the outside.

As described above, according to the third embodiment, in the case where the Gray code counter 1b returns from the illegal state, it is possible to notify to the outside that the return from the illegal state has been performed. Thus, the Gray code is suitably generated.

### Fourth Embodiment

In a fourth embodiment, a Gray code counter capable of switching the setting of the counting direction will be described. The Gray code counter according to the fourth embodiment is referred to as a Gray code counter 1c. In the description of the fourth embodiment, the same components as those of the first embodiment will not be described or will be briefly described.

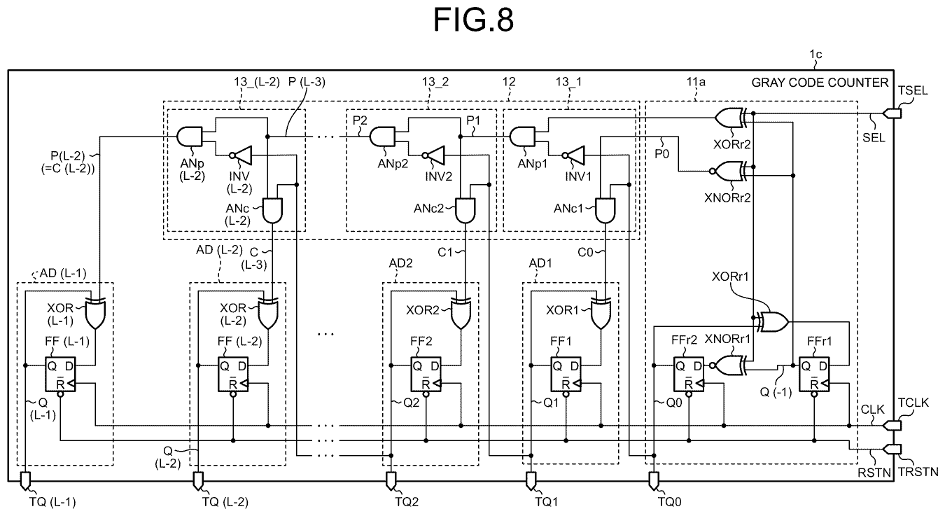

FIG. 8 is a diagram illustrating an example of a circuit configuration of the Gray code counter 1c according to the fourth embodiment. The circuit configuration of the Gray code counter 1c is different from the circuit configuration of the Gray code counter 1 of the first embodiment in that a first circuit block 11a is included instead of the first circuit block 11 and that a selection signal input terminal TSEL is added.

A selection signal SEL for selecting the counting direction is input to the selection signal input terminal TSEL from the outside. In this embodiment, it is assumed that the selection signal SEL being “0” means that the upward direction is set, and the selection signal SEL being “1” means that the downward direction is set.

The first circuit block 11a generates reference signals to be supplied to the second circuit block 12 on the basis of the clock signal CLK and the selection signal SEL.

The first circuit block 11a includes the two reference flip-flops FFr1 and FFr2, two XOR circuits XORr1 and XORr2, and two XNOR circuits XNORr1 and XNORr2.

The clock signal CLK is input to clock terminals of the reference flip-flops FFr1 and FFr2, and the reset signal RSTN is input to reset terminals of the reference flip-flops FFr1 and FFr2.

The signal output from the Q terminal of the reference flip-flop FFr1 is referred to as a data signal Q(−1). Note that the data signal Q(−1) is not output from the Gray code counter 1c to the outside.

The XNOR circuit XNORr1 includes two input terminals, and the Q terminal of the reference flip-flop FFr1 is connected to a first one of the two input terminals. The selection signal input terminal TSEL is connected to a second one of the two input terminals of the XNOR circuit XNORr1. The XNOR circuit XNORr1 calculates the exclusive OR of the data signal Q(−1) output from the Q terminal of the reference flip-flop FFr1 and the selection signal SEL, and performs inversion calculation on a signal obtained by the calculation of the exclusive OR.

An output terminal of the XNOR circuit XNORr1 is connected to the D terminal of the reference flip-flop FFr2. The signal output from the Q terminal of the reference flip-flop FFr2 is referred to as a data signal Q0. The Q terminal of the reference flip-flop FFr2 is connected to a data terminal TQ0. The data terminal TQ0 outputs the data signal Q0 output from the Q terminal of the reference flip-flop FFr2.

The XOR circuit XORr1 includes two input terminals, and the Q terminal of the reference flip-flop FFr2 is connected to a first one of the two input terminals. The selection signal input terminal TSEL is connected to a second one of the two input terminals of the XOR circuit XORr1. The XOR circuit XORr1 calculates the exclusive OR of the selection signal SEL and the data signal Q0 output from the Q terminal of the reference flip-flop FFr2. An output terminal of the XOR circuit XORr1 is connected to the D terminal of the reference flip-flop FFr1.

The data held by the reference flip-flops FFr1 and FFr2 is inverted at the time interval twice the clock cycle of the clock signal CLK regardless of the value of the selection signal SEL. Since the frequency of inversion of the data held by the reference flip-flops FFr1 and FFr2 is set to be lower than the frequency of inversion of data held in one clock cycle, the power consumption of the Gray code counter 1c is relatively reduced.

The Q terminal of the reference flip-flop FFr2 is also connected to the second circuit block 12. Thus, the data signal Q0 output from the Q terminal of the reference flip-flop FFr2 is input to the second circuit block 12.

The XNOR circuit XNORr2 includes two input terminals, and the Q terminal of the reference flip-flop FFr1 is connected to a first one of the two input terminals. The selection signal input terminal TSEL is connected to a second one of the two input terminals of the XNOR circuit XNORr2. The XNOR circuit XNORr2 calculates the exclusive OR of the data signal Q(−1) output from the Q terminal of the reference flip-flop FFr1 and the selection signal SEL, and performs inversion calculation on a signal obtained by the calculation of the exclusive OR. An output terminal of the XNOR circuit XNORr2 is connected to the second circuit block 12.

In the fourth embodiment, the signal output from the XNOR circuit XNORr2 and input to the second circuit block 12 is referred to as a carry generation signal P0.

The XOR circuit XORr2 includes two input terminals, and the Q terminal of the reference flip-flop FFr1 is connected to a first one of the two input terminals. The selection signal input terminal TSEL is connected to a second one of the two input terminals of the XOR circuit XORr2. The XOR circuit XORr2 calculates the exclusive OR of the data signal Q(−1) output from the Q terminal of the reference flip-flop FFr1 and the selection signal SEL. An output terminal of the XOR circuit XORr2 is connected to the second circuit block 12.

The data signal Q0 output from the Q terminal of the reference flip-flop FFr2, the carry generation signal P0 output from the output terminal of the XNOR circuit XNORr2, and a signal output from the output terminal of the XOR circuit XORr2 are input to the second circuit block 12 as reference signals.

In the second circuit block 12, the element block 131 generates the carry signal C0 and the carry generation signal P1 on the basis of the three reference signals input thereto. As a configuration therefor, the element block 13_1 includes the two AND circuits ANp1 and ANc1 and the inverter INV1 as in the first embodiment.

The Q terminal of the reference flip-flop FFr2 included in the first circuit block 11 is connected to the first one of two input terminals of the AND circuit ANc1, and the data signal Q0 output from the Q terminal of the reference flip-flop FFr2 is input thereto. The output terminal of the XNOR circuit XNORr2 is connected to the second one of the two input terminals of the AND circuit ANc1, and the carry generation signal P0 output from the output terminal of the XNOR circuit XNORr2 is input thereto. The AND circuit ANc1 calculates the logical product of the data signal Q0 and the carry generation signal P0, and a signal obtained by the calculation is output as the carry signal C0 from the output terminal of the AND circuit ANc1.

The Q terminal of the reference flip-flop FFr2 is connected to the input terminal of the inverter INV1, and the data signal Q0 output from the Q terminal of the reference flip-flop FFr2 is input thereto. The inverter INV1 performs inversion calculation on the data signal Q0.

The output terminal of the XOR circuit XORr2 is connected to the first one of two input terminals of the AND circuit ANp. The output terminal of the inverter INV1 is connected to the second one of the two input terminals of the AND circuit ANp1, and the data signal Q0 inverted by the inverter INV1 is input thereto. The AND circuit ANp1 calculates the logical product of the signal output from the output terminal of the XOR circuit XORr2 and the inverted data signal Q0. The signal obtained by the logical product calculation is output from the element block 13_1 as the carry generation signal P1. The (L−3) element blocks 13-2 to 13-(L−2) respectively generate carry signals C1 to C(L−2) on the basis of the carry generation signal P1.

Specifically, the second circuit block 12 generates the carry signal C0 by the logical product of the carry generation signal P0 output from the output terminal of the XNOR circuit XNORr2 and the data signal Q0 output from the Q terminal of the reference flip-flop FFr2. In addition, the second circuit block 12 generates the carry signals C1 to C(L−2) on the basis of the signal output from the XOR circuit XORr2 and the data signal Q0 output from the Q terminal of the reference flip-flop FFr2.

In a case where the selection signal SEL is set to “1”, namely, in a case where the setting of the downward direction is selected, the three reference signals input to the second circuit block 12 are caused to transition as in the Gray code counter 1 of the first embodiment. Therefore, each signal related to the Gray code counter 1c is caused to transition similarly to the transition illustrated in FIGS. 2 and 3. Thus, the Gray code counter 1c operates as the down counter.

In a case where the selection signal SEL is set to “0”, namely, in a case where the setting of the upward direction is selected, each of the reference signal input from the XNOR circuit XNORr2 to the second circuit block 12 and the reference signal input from the XOR circuit XORr2 to the second circuit block 12 is inverted.

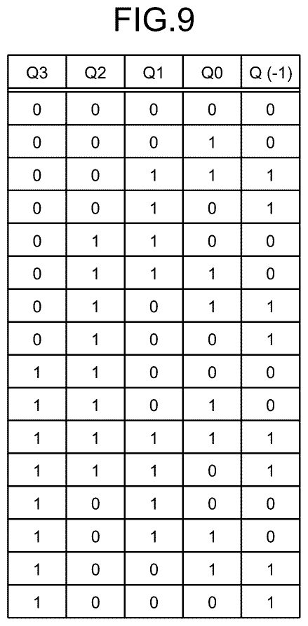

FIG. 9 is a truth table of the case where the selection signal SEL is set to “0”. Note that, in this drawing, L is assumed to be “4” to facilitate understanding.

A data signal Q3 indicating the value of the most significant bit of the four-bit Gray code Q0-Q3 is “0” in the first half of the count cycle and is “1” in the second half of the count cycle. Thus, the Gray code counter 1c operates as a counter whose counting direction is in the upward direction, namely, an up counter.

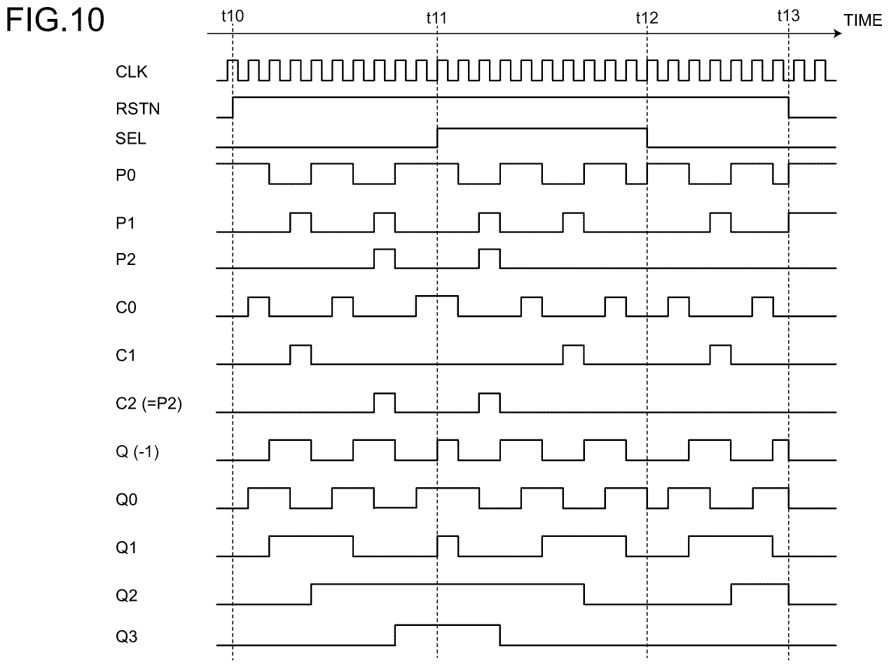

FIG. 10 is a timing chart illustrating an example of transition of various signals in the Gray code counter 1c according to the fourth embodiment. Note that, also in this drawing, L is assumed to be “4”.

In the example illustrated in FIG. 10, in a period during which the reset signal RSTN is canceled (period from timing t10 to timing t13), the selection signal SEL is set to “0” in a period from timing t10 to timing t11, and the selection signal SEL is set to “1” in a period from timing t11 to timing t12. It can be understood that the Gray code is generated in the counting direction of the upward direction in the period during which the selection signal SEL is set to “0”, and the Gray code is generated in the counting direction of the downward direction in the period during which the selection signal SEL is set to “1”.

As described above, according to the fourth embodiment, the Gray code counter 1c is configured to be capable of switching the setting of the counting direction. In addition, similarly to the first embodiment, the inversion frequency at which the data held by the reference flip-flops (for example, the reference flip-flops FFr1 and FFr2) necessary for the calculation of the reference signals is inverted is reduced, and accordingly, the power consumption of the Gray code counter 1c is reduced. Therefore, the Gray code is suitably generated.

### Fifth Embodiment

If a soft error occurs in the Gray code counter 1c according to the fourth embodiment, the counting direction may be reversed.

In a fifth embodiment, description is given on a Gray code counter configured to be capable of switching the setting of the counting direction and to which a return circuit for returning from an illegal state is applied.

The Gray code counter according to the fifth embodiment is referred to as a Gray code counter 1d. In the description of the fifth embodiment, the same components as those of the fourth embodiment will not be described or will be briefly described.

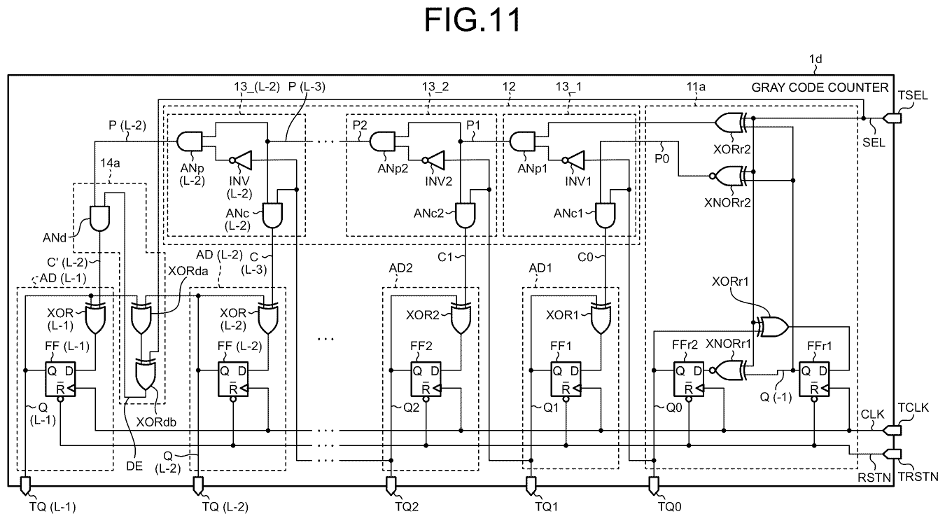

FIG. 11 is a diagram illustrating an example of a circuit configuration of the Gray code counter 1d according to the fifth embodiment. The circuit configuration of the Gray code counter 1d is different from the circuit configuration of the Gray code counter 1c of the fourth embodiment in that a return circuit 14a is added.

The return circuit 14a disables the carry signal C′(L−2) input to the adder AD(L−1) depending on the values of the data signals Q(L−1) and Q(L−2), which are the values of the most significant two bits of the Gray code, and the selection signal SEL.

As described above, in the counting in the downward direction, the carry signal C(L−2) changes from “0” to “1” only at the timing when the value of the data signal Q(L−1) is equal to the value of the data signal Q(L−2). On the other hand, in the counting in the upward direction, the carry signal C(L−2) changes from “0” to “1” only at timing when the value of the data signal Q(L−1) and the value of the data signal Q(L−2) are different.

Therefore, the return circuit 14a is configured to be switchable on the basis of the selection signal SEL as to whether in which case the carry signal is disabled between the case where the value of the data signal Q(L−1) and the value of the data signal Q(L−2) are equal to each other and the case where these values are different from each other.

The return circuit 14a includes an XOR circuit XORda, an XOR circuit XORdb, and the AND circuit ANd.

The XOR circuit XORda includes two input terminals, and the Q terminal of the flip-flop FF(L−1) included in the adder AD(L−1) is connected to a first one of the two input terminals. A second one of the two input terminals of the XOR circuit XORda is connected to the Q terminal of the flip-flop FF(L−2) included in the adder AD(L−2). The XOR circuit XORda calculates the exclusive OR of the data signal Q(L−1) output from the Q terminal of the flip-flop FF(L−1) and the data signal Q(L−2) output from the Q terminal of the flip-flop FF(L−2).

The XOR circuit XORdb includes two input terminals, and an output terminal of the XOR circuit XORda is connected to a first one of the two input terminals. The selection signal input terminal TSEL is connected to a second one of the two input terminals of the XOR circuit XORdb. The XOR circuit XORdb calculates the exclusive OR of a signal output from the XOR circuit XORda and the selection signal SEL.

In the fifth embodiment, a signal output from the XOR circuit XORdb is used as the disable signal DE.

The output terminal of the AND circuit ANp(L−2) included in the element block 13_(L−2) is connected to the first one of two input terminals of the AND circuit ANd, and the carry generation signal P(L−2) is input thereto. An output terminal of the XOR circuit XORdb is connected to the second one of the two input terminals of the AND circuit ANd, and the disable signal DE is input thereto. The AND circuit ANd calculates the logical product of the carry generation signal P(L−2) and the disable signal DE.

The output terminal of the AND circuit ANd is connected to the adder AD(L−1). The signal output from the AND circuit ANd is input to the adder AD(L−1) as the carry signal C′(L−2).

In the period of time during which the selection signal SEL is set to “1”, namely, in the period of time during which the setting of the downward direction is selected, the disable signal DE is “1” only when the value of the data signal Q(L−1) and the value of the data signal Q(L−2) are equal to each other. In the period of time during which the selection signal SEL is set to “0”, namely, in the period of time during which the setting of the upward direction is selected, the disable signal DE is “1” only when the value of the data signal Q(L−1) and the value of the data signal Q(L−2) are different from each other.

By using the selection signal SEL, the return circuit 14a can set the disable signal DE to “0” in a case where the counting direction is inverted due to the illegal state regardless of whether the counting direction is the downward direction or the upward direction. Therefore, regardless of whether the counting direction is the downward direction or the upward direction, it is possible to disable the carry signal C′(L−2) in response to the inversion of the counting direction due to the illegal state.

In the case where the carry signal C′(L−2) is disabled, a change from “0” to “1” of the carry signal C′(L−2) due to a change from “0” to “1” of the carry generation signal P(L−2) is suppressed, and the counting direction is returned to the direction as of the time before the occurrence of the illegal state. Thus, the Gray code counter 1d returns from the illegal state.

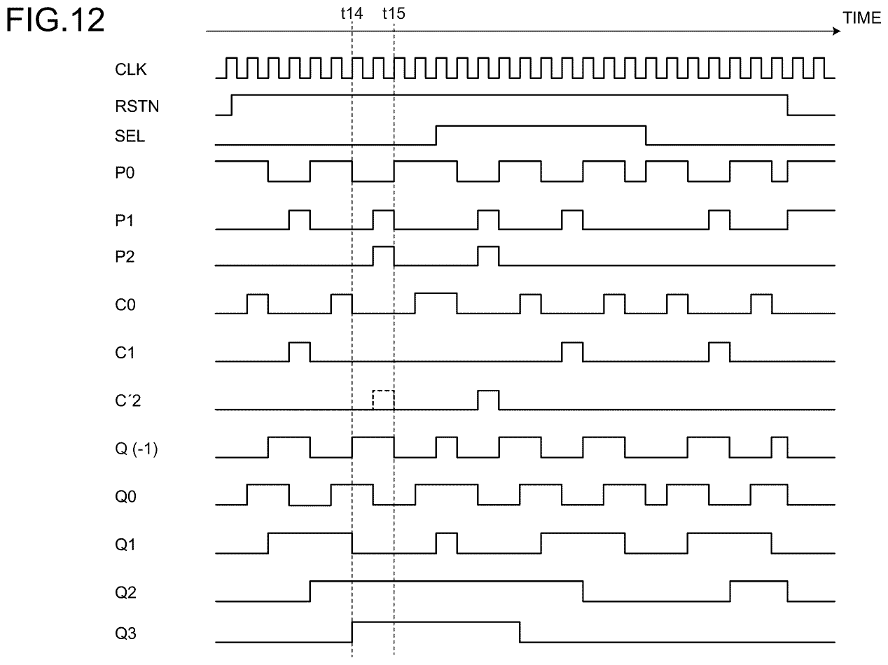

FIG. 12 is a timing chart illustrating an example of transition of various signals in the Gray code counter 1d according to the fifth embodiment. Also in this drawing, L is assumed to be “4” to facilitate understanding.

In the example illustrated in FIG. 12, during the counting in the upward direction, the value of the data signal Q3 changes due to a soft error, and the counting direction changes to the downward direction (timing t14).

After timing t14, the change from “0” to “1” of the carry signal C′2 due to the change from “0” to “1” of the carry generation signal P2 is suppressed, and accordingly, a change of the data signal Q3 from “1” to “0” is suppressed. As a result, the counting direction is returned to the upward direction at timing t15.

As described above, according to the fifth embodiment, the Gray code counter 1d can return from the illegal state even when the Gray code counter 1d enters the illegal state. Thus, the Gray code is suitably generated.

### Sixth Embodiment

In a sixth embodiment, description will be given on a Gray code counter capable of externally notifying that a return from the illegal state has been performed in a case of returning from the illegal state.

A Gray code counter according to the sixth embodiment is referred to as a Gray code counter 1e. In the description of the sixth embodiment, the same components as those of the fifth embodiment will not be described or will be briefly described.

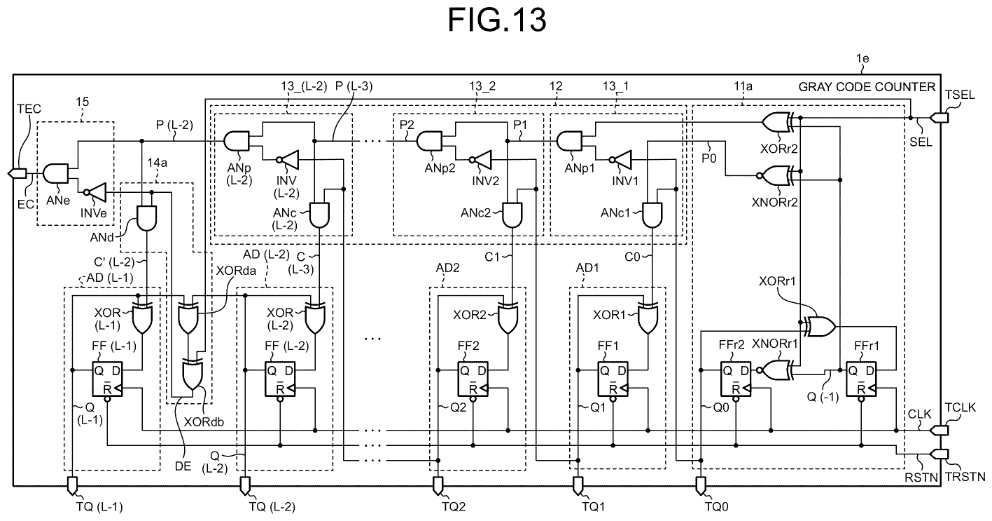

FIG. 13 is a diagram illustrating an example of a circuit configuration of the Gray code counter 1e according to the sixth embodiment. The circuit configuration of the Gray code counter 1e is different from the circuit configuration of the Gray code counter 1d of the fifth embodiment in that the status generation circuit 15 is added and that the status signal output terminal TEC is added.

The status generation circuit 15 includes the inverter INVe and the AND circuit ANe.

The output terminal of the XOR circuit XORdb is connected to the input terminal of the inverter INVe, and the disable signal DE output from the XOR circuit XORdb is input thereto. The inverter INVe performs inversion calculation on the disable signal DE input thereto.

The connection and the operation of the AND circuit ANe are the same as the connection and the operation of the AND circuit ANe described with reference to FIG. 6.

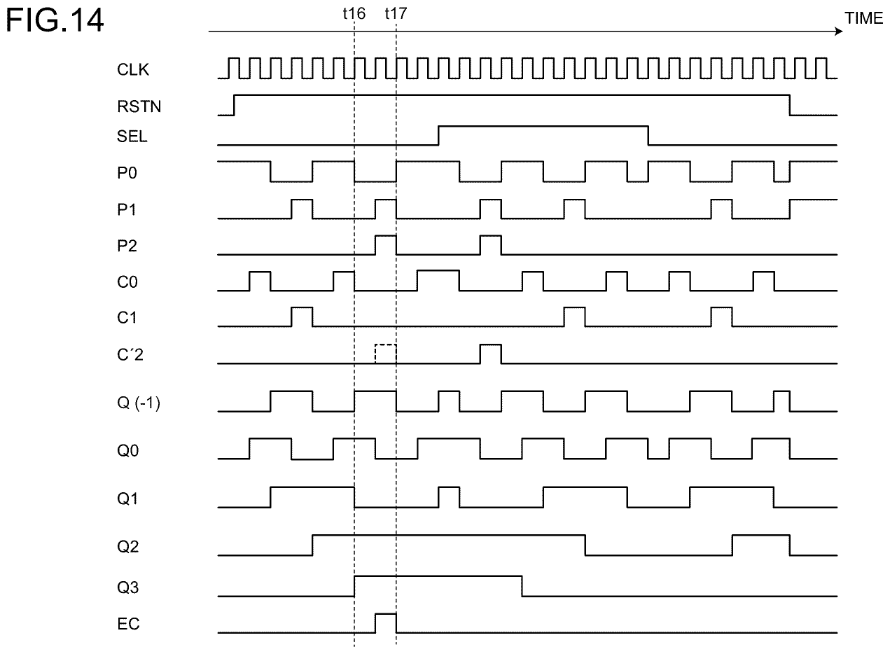

FIG. 14 is a timing chart illustrating an example of transition of various signals in the Gray code counter 1e according to the sixth embodiment. Also in this drawing, L is assumed to be “4” to facilitate understanding.

During the counting in the upward direction, the value of the data signal Q3 changes due to a soft error, and the counting direction changes to the downward direction (timing t16).

After timing t16, the change from “0” to “1” of the carry signal C′2 due to the change from “0” to “1” of the carry generation signal P2 is disabled, and the counting direction is corrected from the downward direction to the upward direction.

When the change from “0” to “1” of the carry signal C′2 due to the change from “0” to “1” of the carry generation signal P2 is disabled, the status signal EC changes from “0” to “1” as the carry generation signal P2 changes from “0” to “1”. The status signal EC changes from “0” to “1” and thereafter returns from “1” to “0” at the next rising edge of the clock CLK (timing t17).

Therefore, the notification that the counting direction has been corrected, in other words, the notification that a return from the illegal state has been performed is output to the outside.

As described above, according to the sixth embodiment, in a case where the Gray code counter 1e returns from the illegal state, it is possible to notify to the outside that the return from the illegal state has been performed. Thus, the Gray code is suitably generated.

### Seventh Embodiment

In a seventh embodiment, a Gray code counter which is configured to perform up-counting and to which a return circuit for returning from the illegal state is applied will be described.

The Gray code counter according to the seventh embodiment is referred to as a Gray code counter 1f. In the description of the seventh embodiment, the same components as those of the second embodiment will not be described or will be briefly described.

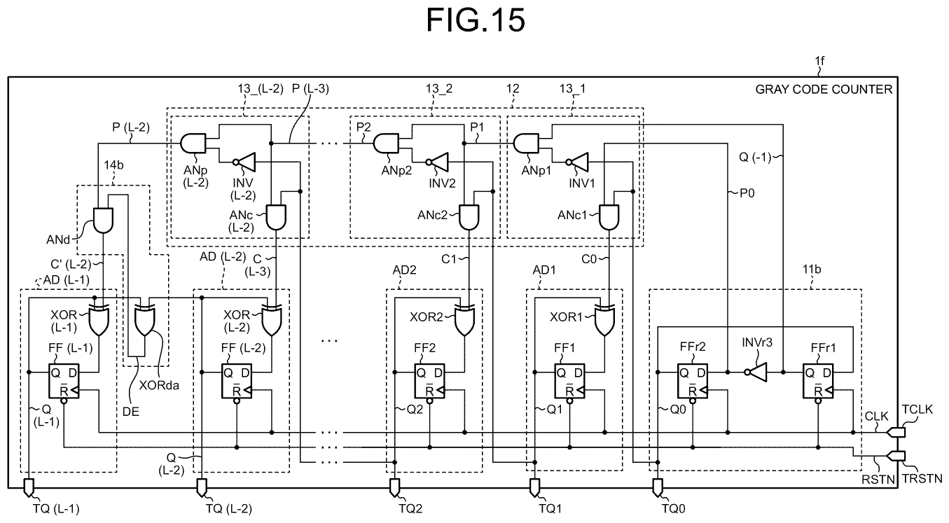

FIG. 15 is a diagram illustrating an example of a circuit configuration of the Gray code counter 1f according to the seventh embodiment. The circuit configuration of the Gray code counter 1f is different from that of the Gray code counter 1a of the second embodiment in that a first circuit block 11b is included instead of the first circuit block 11 and that a return circuit 14b is included instead of the return circuit 14.

The first circuit block 11b generates reference signals to be supplied to the second circuit block 12 on the basis of the clock signal CLK.

The first circuit block 11b includes the two reference flip-flops FFr1 and FFr2 and an inverter INVr3.

The Q terminal of the reference flip-flop FFr1 is connected to an input terminal of the inverter INVr3. An output terminal of the inverter INVr3 is connected to the D terminal of the reference flip-flop FFr2. The inverter INVr3 performs inversion calculation on the signal output from the reference flip-flop FFr1.

The Q terminal of the reference flip-flop FFr2 is connected to the D terminal of the reference flip-flop FFr1. The signal output from the Q terminal of the reference flip-flop FFr2 is input to the D terminal of the reference flip-flop FFr1.

Therefore, the data held by the reference flip-flops FFr1 and FFr2 is inverted at the time interval twice the clock cycle of the clock signal CLK. Since the frequency of inversion of the data held by the reference flip-flops FFr1 and FFr2 is set to be lower than the frequency of inversion of data held in one clock cycle, the power consumption of the Gray code counter 1f is relatively reduced.

The signal output from the Q terminal of the reference flip-flop FFr2 is referred to as the data signal Q0. The Q terminal of the reference flip-flop FFr2 is connected to the data terminal TQ0. The data terminal TQ0 outputs the data signal Q0 output from the Q terminal of the reference flip-flop FFr2.

The signal output from the Q terminal of the reference flip-flop FFr2 (namely, the data signal Q0), the signal output from the Q terminal of the reference flip-flop FFr1, and a signal output from the output terminal of the inverter INVr3 are input as reference signals to the second circuit block 12.

In the seventh embodiment, the signal output from the Q terminal of the reference flip-flop FFr1 is regarded as the data signal Q(−1). The signal output from the output terminal of the inverter INVr3 is referred to as the carry generation signal P0.

In the second circuit block 12, the element block 131 generates the carry signal C0 and the carry generation signal P1 on the basis of the data signals Q0 and Q(−1) and the carry generation signal P0. As a configuration therefor, the element block 13_1 includes the two AND circuits ANp1 and ANc1 and the inverter INV1 as in the second embodiment.

The Q terminal of the reference flip-flop FFr2 included in the first circuit block 11b is connected to the first one of the two input terminals of the AND circuit ANc1. The output terminal of the inverter INVr3 is connected to the second one of the two input terminals of the AND circuit ANc1, and the carry generation signal P0 output from the inverter INVr3 is input thereto. The AND circuit ANc1 calculates the logical product of the data signal Q0 and the carry generation signal P0. The signal obtained by this calculation is output as the carry signal C0 from the output terminal of the AND circuit ANc1.

The connection and the operation of the inverter INV1 are the same as the connection and the operation of the inverter INV1 described with reference to FIG. 1 in the first embodiment.

The Q terminal of the reference flip-flop FFr1 included in the first circuit block 11b is connected to the first one of the two input terminals of the AND circuit ANpL. The output terminal of the inverter INV1 is connected to the second one of the two input terminals of the AND circuit ANpL. The AND circuit ANp1 calculates the logical product of the data signal Q(−1) output from the Q terminal of the reference flip-flop FFr1 and the data signal Q0 inverted by the inverter INV1. The signal obtained by the logical product calculation is output from the element block 13_1 as the carry generation signal PL. The (L−3) element blocks 13-2 to 13-(L−2) generate carry signals C1 to C(L−3) and the carry generation signal P(L−2) on the basis of the carry generation signal P1. The carry generation signal P(L−2) is used as the carry signal C′(L−2) via the return circuit 14b.

Specifically, the second circuit block 12 generates the carry signal C0 by the logical product of the carry generation signal P0 output from the inverter INVr3 and the data signal Q0 output from the Q terminal of the reference flip-flop FFr2. In addition, the second circuit block 12 generates the carry signals of the adders AD2 to AD(L−2) (more precisely, the carry signals C1 to C(L−3) and the carry generation signal P(L−2)) on the basis of the data signal Q(−1) output from the Q terminal of the reference flip-flop FFr1 and the data signal Q0 output from the Q terminal of the reference flip-flop FFr2.

The return circuit 14b disables the carry signal C′(L−2) input to the adder AD(L−1) depending on the values of the data signals Q(L−1) and Q(L−2) which are the values of the most significant two bits of the Gray code.

In the counting in the upward direction, the carry signal C′(L−2) changes from “0” to “1” only at timing when the value of the data signal Q(L−1) and the value of the data signal Q(L−2) are different.

Therefore, in a case where the value of the data signal Q(L−1) and the value of the data signal Q(L−2) are equal to each other, the return circuit 14b disables the carry signal.

More specifically, the return circuit 14b includes the XOR circuit XORda and the AND circuit ANd.

The XOR circuit XORda includes two input terminals, and the Q terminal of the flip-flop FF(L−1) included in the adder AD(L−1) is connected to the first one of the two input terminals. The second one of the two input terminals of the XOR circuit XORda is connected to the Q terminal of the flip-flop FF(L−2) included in the adder AD(L−2). The XOR circuit XORda calculates the exclusive OR of the data signal Q(L−1) output from the Q terminal of the flip-flop FF(L−1) and the data signal Q(L−2) output from the Q terminal of the flip-flop FF(L−2).

In the seventh embodiment, the signal output from the XOR circuit XORda is used as the disable signal DE.

The output terminal of the AND circuit ANp(L−2) included in the element block 13_(L−2) is connected to a first one of two input terminals of the AND circuit ANd, and the carry generation signal P(L−2) output from the AND circuit ANp(L−2) is input thereto. The output terminal of the XOR circuit XORda is connected to the second one of the two input terminals of the AND circuit ANd, and the disable signal DE output from the XOR circuit XORda is input thereto.

The output terminal of the AND circuit ANd is connected to the adder AD(L−1). The signal output from the AND circuit ANd is input to the adder AD(L−1) as the carry signal C′(L−2).

In the period of time during which the counting in the upward direction is being performed, the disable signal DE is “1” only when the value of the data signal Q(L−1) and the value of the data signal Q(L−2) are different from each other. Therefore, in a case where the inversion of the counting direction due to the illegal state occurs at the time of the counting operation in the upward direction, the disable signal DE changes from “1” to “0”, and accordingly, the carry signal C′(L−2) is disabled.

In the case where the carry signal C′(L−2) is disabled, the change from “0” to “1” of the carry signal C′(L−2) due to the change from “0” to “1” of the carry generation signal P(L−2) is suppressed, and the counting direction is returned to the direction as of the time before the occurrence of the illegal state. Thus, the Gray code counter 1f returns from the illegal state.

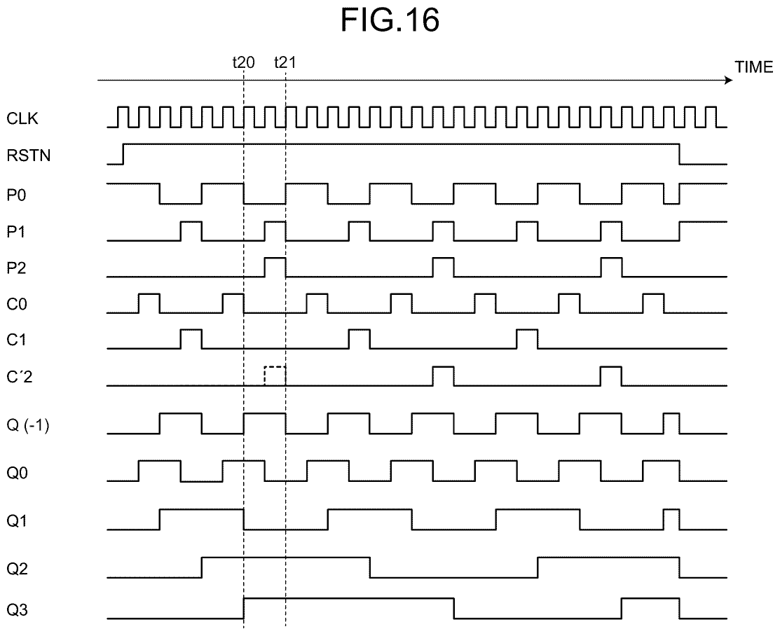

FIG. 16 is a timing chart illustrating an example of transition of various signals in the Gray code counter 1f according to the seventh embodiment. Also in this drawing, L is assumed to be “4” to facilitate understanding.

In the example illustrated in FIG. 16, during the counting in the upward direction, the value of the data signal Q3 changes due to a soft error, and the counting direction changes to the downward direction (timing t20).

After timing t20, the change from “0” to “1” of the carry signal C′2 due to the change from “0” to “1” of the carry generation signal P2 is suppressed, and accordingly, a change of the data signal Q3 from “1” to “0” is suppressed. As a result, after timing t21, the counting direction is corrected from the downward direction to the upward direction.

As described above, according to the seventh embodiment, even when the Gray code counter 1f enters the illegal state, the Gray code counter 1f can return from the illegal state. Thus, the Gray code is suitably generated.

### Eighth Embodiment

In an eighth embodiment, description will be given on a Gray code counter capable of externally notifying that a return from the illegal state has been performed in a case of returning from the illegal state.

The Gray code counter according to the eighth embodiment is referred to as a Gray code counter 1g. In the description of the eighth embodiment, the same components as those of the seventh embodiment will not be described or will be briefly described.

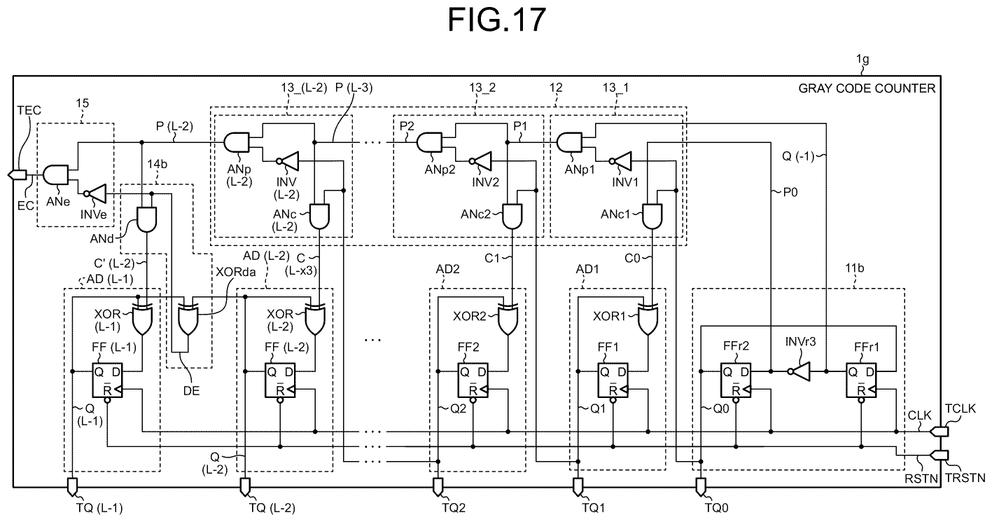

FIG. 17 is a diagram illustrating an example of a circuit configuration of the Gray code counter 1g according to the eighth embodiment. The circuit configuration of the Gray code counter 1g is different from the circuit configuration of the Gray code counter 1f of the seventh embodiment in that, the status generation circuit 15 and the status signal output terminal TEC are added.

The status generation circuit 15 includes the inverter INVe and the AND circuit ANe.

The output terminal of the XOR circuit XORda is connected to the input terminal of the inverter INVe, and the disable signal DE output from the XOR circuit XORda is input thereto. The inverter INVe performs inversion calculation on the disable signal DE input thereto.

The connection and the operation of the AND circuit ANe are the same as the connection and the operation of the AND circuit ANe described with reference to FIG. 6.

Therefore, the AND circuit ANe outputs “1” in the case where the change from “0” to “1” of the carry signal C′(L−2) due to the change from “0” to “1” of the carry generation signal P(L−2) is suppressed, in other words, in a case where a return from the illegal state is performed. The signal output from the AND circuit ANe is output to the outside from the status signal output terminal TEC as the status signal EC.

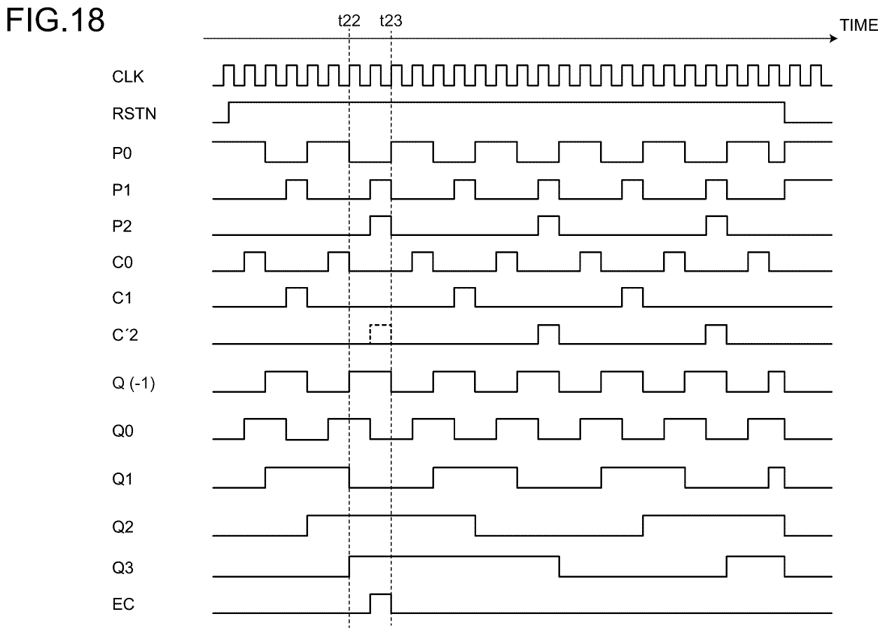

FIG. 18 is a timing chart illustrating an example of transition of various signals in the Gray code counter 1g according to the eighth embodiment. Also in this drawing, L is assumed to be “4” to facilitate understanding.

In the example illustrated in FIG. 18, during the counting in the upward direction, the value of the data signal Q3 changes due to a soft error, and the counting direction changes in the downward direction (timing t22).

After timing t22, the change from “0” to “1” of the carry signal C′2 due to the change from “0” to “1” of the carry generation signal P2 is suppressed, and accordingly, the change of the data signal Q3 from “1” to “0” is suppressed. As a result, the counting direction is returned to the upward direction at timing t23.

As described above, according to the eighth embodiment, the Gray code counter 1g can return from the illegal state even when the Gray code counter 1g enters the illegal state. Moreover, in a case where the Gray code counter 1g returns from the illegal state, it is possible to notify to the outside that the return from the illegal state has been performed. Thus, the Gray code is suitably generated.

### Ninth Embodiment

The Gray code changes only by one bit per clock cycle. Therefore, a Gray code counter has a feature that it is possible to suppress the influence of an error that may occur when an output value of the Gray code counter is acquired asynchronously with the operation of the Gray code counter. Due to this feature, the Gray code counter can be utilized in a device that handles two different clock signals, for example.

A Gray code counter according to a ninth embodiment is included in a semiconductor device that receives data in synchronization with a first clock signal and processes the data on the basis of a second clock signal. As an example of a system including such a semiconductor device, a memory system SYS will be described.

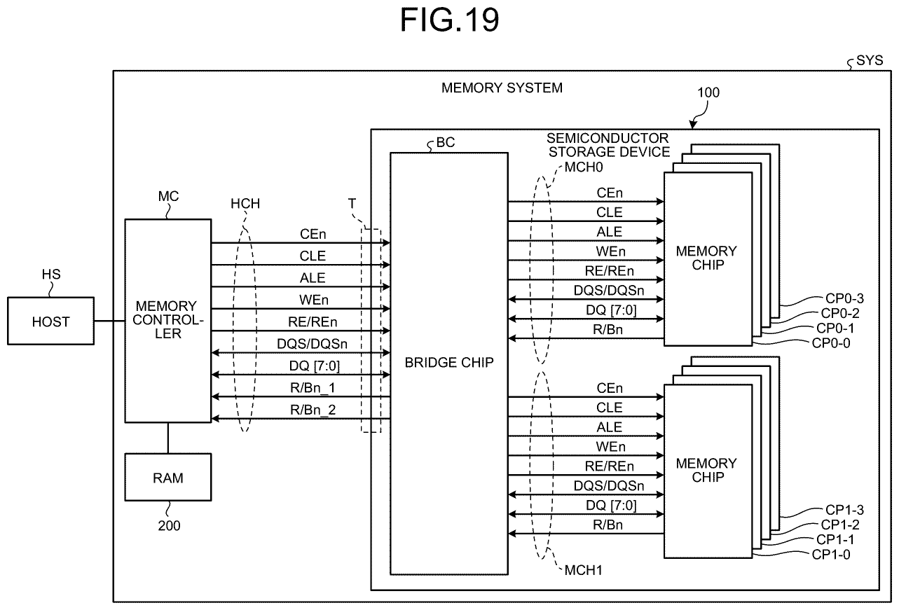

FIG. 19 is a diagram illustrating an example of a configuration of a memory system SYS according to a ninth embodiment.

The memory system SYS can be connected to a host HS. The standard to which a communication path connecting the host HS and the memory system SYS and the communication via the communication path conforms are not limited to specific standards. The host HS is, for example, a personal computer, a portable information terminal, or a server. The host HS transmits various commands including a write command, a read command, or the like to the memory system SYS.

The memory system SYS includes a semiconductor storage device 100, a memory controller MC, and a random access memory (RAM) 200.

The memory controller MC is a control circuit that controls the semiconductor storage device 100. As part of the control of the semiconductor storage device 100, the memory controller MC executes data transfer between the host HS and the semiconductor storage device 100 in response to an access command from the host HS.

The RAM 200 provides the memory controller MC with a storage area such as a buffer area, a cache area, and an area into which programs are loaded. For example, the memory controller MC can buffer transfer data between the host HS and the semiconductor storage device 100 in the RAM 200. In addition, the memory controller MC loads a firmware program into the RAM 200 and uses the program or buffers or caches various types of management data in the RAM 200.

The semiconductor storage device 100 includes a group of external terminals T, a bridge chip BC, and a plurality of memory chips CP0-0 to CP0-3 and CP1-0 to CP1-3.

Note that the bridge chip BC is an example of the semiconductor device of the ninth embodiment.

Each of the memory chips CP0-0 to CP0-3 and CP1-0 to CP1-3 is, for example, a memory chip of a nonvolatile memory such as a NAND flash memory.

The semiconductor storage device 100 can be implemented as a multi-chip package (MCP) in which the memory chips CP0-0 to CP0-3 and the memory chips CP1-0 to CP1-3 are respectively stacked. In a case where the semiconductor storage device 100 is implemented as the MCP, in the semiconductor storage device 100, the periphery of the bridge chip BC and the memory chips CP0-0 to CP0-3 and CP1-0 to CP1-3 may be sealed with a molding resin.

In addition, the semiconductor storage device 100 includes a plurality of channels connecting the memory chips CP0-0 to CP0-3 and CP1-0 to CP1-3 and the bridge chip BC. Each of the channels is referred to as a memory channel MCH in the sense that the channel connects the NAND flash memory.

In the example of FIG. 19, the semiconductor storage device 100 includes memory channels MCH0 and MCH1 as the memory channels MCH. Moreover, the four memory chips CP0-0 to CP0-3 are connected to the bridge chip BC via the memory channels MCH0, and the four memory chips CP1-0 to CP1-3 are connected to the bridge chip BC via the memory channels MCH1.

Each of the memory channels MCH is configured to comply with a predetermined standard. In a case where each of the memory chips CP0-0 to CP0-3 and CP1-0 to CP1-3 is the NAND flash memory, the predetermined standard is, for example, the toggle DDR standard.

Note that the number of memory chips CP included in the semiconductor storage device 100 is not limited to eight. In addition, the number of memory channels MCH connecting the bridge chip BC and the memory chips CP is not limited to two. The number of memory chips CP connected to one memory channel MCH is not limited to four.

Hereinafter, each of the memory chips CP0-0 to CP0-3 and CP1-0 to CP1-3 may be referred to as a memory chip CP.

The semiconductor storage device 100 is connected to the memory controller MC via one channel. This one channel is referred to as a host channel HCH in the sense that the channel is on the host side as viewed from the bridge chip BC side.

The host channel HCH is configured on the basis of a predetermined standard. In the case where each of the memory chips CP is the NAND flash memory, the predetermined standard is, for example, the toggle DDR standard.

The host channel HCH includes a signal line that transfers a chip enable signal CEn, a signal line that transfers a command latch signal CLE, a signal line that transfers an address latch signal ALE, a signal line that transfers a write enable signal WEn, a signal line that transfers a read enable signal RE/REn, a signal line that transfers a data strobe signal DQS/DQSn, a signal line that transfers a data signal DQ(7:0) with a predetermined bit width (here, as an example, an 8-bit width), a signal line that transfers a ready/busy signal R/Bn_1, and a signal line that transfers a ready/busy signal R/Bn_2. Note that “n” added at the end of a symbol representing a signal represents that the signal is caused to operate with the negative logic. Whether each of the signals is caused to operate with the negative logic or the positive logic can be optionally designed.

The chip enable signal CEn is a signal for enabling a memory chip CP to be accessed. The data strobe signal DQS/DQSn is a signal instructing a counterpart device to capture data transmitted by the data signal DQ(7:0). The data strobe signal DQS/DQSn is a differential signal including a data strobe signal DQS and a data strobe signal DQSn. The command latch enable signal CLE is a signal indicating that the data signal DQ(7:0) is a command. The address latch enable signal ALE is a signal indicating that the data signal DQ(7:0) is an address. The write enable signal WEn is a signal instructing the counterpart device to capture a command or an address transmitted by the data signal DQ(7:0). The read enable signal RE/REn is a signal instructing the counterpart device to output the data signal DQ(7:0). The read enable signal RE/REn is a differential signal configured by the read enable signal RE and the read enable signal REn. The ready/busy signal R/Bn_1 and the ready/busy signal R/Bn_2 are signals indicating whether being in a ready state in which reception of a command is waited for or a busy state in which a command cannot be executed even if the command is received. Note that the configuration of the signal line that transfers the ready/busy signal R/Bn included in the host channel HCH is not limited to the above example. For example, the host channel HCH may include one signal line for transferring one ready/busy signal R/Bn generated by wired OR connection or the like from the ready/busy signal R/Bn related to the memory channel MCH0 and the ready/busy signal R/Bn related to the memory channel MCH1.

Each of the memory channels MCH0 and MCH1 can transmit and receive a signal group of the same type as the signal group of the host channel HCH. That is, each of the memory channels MCH0 and MCH1 includes a signal line that transfers the chip enable signal CEn, a signal line that transfers the command latch signal CLE, a signal line that transfers the address latch signal ALE, a signal line that transfers the write enable signal WEn, a signal line that transfers the read enable signal RE/REn, a signal line that transfers the data strobe signal DQS/DQSn, a signal line group that transfers a data signal DQ(7:0), and a signal line that transfers the ready/busy signal R/Bn.

When writing of data (referred to as write data) is requested by a write command from the host HS, the memory controller MC temporarily stores the write data in the RAM 200. Then, the memory controller MC performs various types of processing such as error correction coding on the write data stored in the RAM 200 and transfers the processed write data to the bridge chip BC as the data signal DQ(7:0). When the data signal DQ(7:0) is transferred to the bridge chip BC, the memory controller MC transfers the data strobe signal DQS/DQSn toggled to synchronize with the transfer of the data signal DQ(7:0) to the bridge chip BC.

The bridge chip BC sequentially captures the write data transferred as the data signal DQ(7:0) from the memory controller MC as the data strobe signal DQS/DQSn is toggled. The bridge chip BC transfers the captured write data to any one of the memory chips CP as the data signal DQ(7:0). When the data signal DQ(7:0) is transferred to the memory chip CP, the bridge chip BC transfers the data strobe signal DQS/DQSn toggled to synchronize with the transfer of the data signal DQ(7:0) to the memory chip CP.

When reading of data (referred to as read data) is requested by a read command from the host HS, the memory controller MC instructs the memory chip CP storing the read data to perform a read operation via the bridge chip BC. The memory chip CP in which the read data is stored transfers the read data to the bridge chip BC as the data signal DQ(7:0) in response to the instruction of the read operation. When the data signal DQ(7:0) is transferred to the bridge chip BC, the memory chip CP transfers the data strobe signal DQS/DQSn toggled to synchronize with the transfer of the data signal DQ(7:0) to the bridge chip BC.

The bridge chip BC sequentially captures the read data transferred as the data signal DQ(7:0) from the memory chip CP as the data strobe signal DQS/DQSn is toggled. The bridge chip BC transfers the captured read data to the memory controller MC as the data signal DQ(7:0). When the data signal DQ(7:0) is transferred to the memory controller MC, the bridge chip BC transfers the data strobe signal DQS/DQSn toggled to synchronize with the transfer of the data signal DQ(7:0) to the memory controller MC.

In this manner, the bridge chip BC captures data transferred from an external device (in this case, one of the memory controller MC and the memory chip CP) by the data strobe signal DQS/DQSn toggled to synchronize with the transfer of the data. Then, the bridge chip BC transfers the captured data to another external device (in this case, the other one of the memory controller MC and the memory chip CP).

The bridge chip BC includes an oscillation circuit (an oscillation circuit 101 to be described later) that generates a clock signal used for various types of processing. The clock signal generated by the oscillation circuit 101 is referred to as a clock signal CLK0. The bridge chip BC performs various types of processing using the clock signal CLK0 on data captured using the data strobe signal DQS/DQSn.

The frequency of the clock signal CLK0 fluctuates due to various factors including fluctuation in the ambient temperature of the oscillation circuit 101, fluctuation in the voltage supplied to the oscillation circuit 101, and others. However, in order to perform processing on the data captured using the data strobe signal DQS/DQSn without fail, the frequency of the clock signal CLK0 is required to be higher than or equal to the frequency of the data strobe signal DQS/DQSn. Therefore, the bridge chip BC has a configuration described below in order to maintain the frequency of the clock signal CLK0 to be higher than or equal to the frequency of the data strobe signal DQS/DQSn.

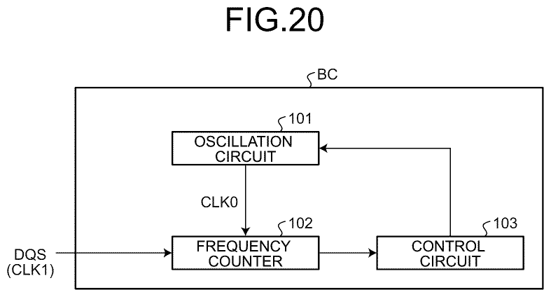

FIG. 20 is a diagram illustrating an example of a partial configuration of the bridge chip BC according to the ninth embodiment. The bridge chip BC includes an oscillation circuit 101, a frequency counter 102, and a control circuit 103.

The oscillation circuit 101 is an oscillator capable of controlling an oscillation frequency by input from an external terminal. The oscillation circuit 101 generates the clock signal CLK0. In one example, the oscillation circuit 101 is a voltage-controlled oscillator (VCO).

The data strobe signal DQS/DQSn transferred from the outside (the memory controller MC or the memory chip CP) is input to the frequency counter 102. The frequency counter 102 counts the data strobe signal DQS/DQSn input thereto. The count by the frequency counter 102 corresponds to the count of the frequency of the data strobe signal DQS/DQSn.

Note that it is based on the premise herein for easy understanding that the data strobe signal DQS of the data strobe signal DQS/DQSn is input to the frequency counter 102 and that the frequency of the data strobe signal DQS is counted. The frequency of the data strobe signal DQS is equal to the frequency of the data strobe signal DQSn.

In addition, the data strobe signal DQS input to the frequency counter 102 is treated as a signal similar to the clock signal CLK0 for convenience and may be referred to as a clock signal CLK1.

The control circuit 103 adjusts the frequency of the clock signal CLK0 on the basis of the count value by the frequency counter 102 such that the frequency of the clock signal CLK0 is higher than or equal to the frequency of the data strobe signal DQS/DQSn. The control circuit 103 changes the frequency of the clock signal CLK0 by inputting a control signal to a control terminal of the oscillation circuit 101.

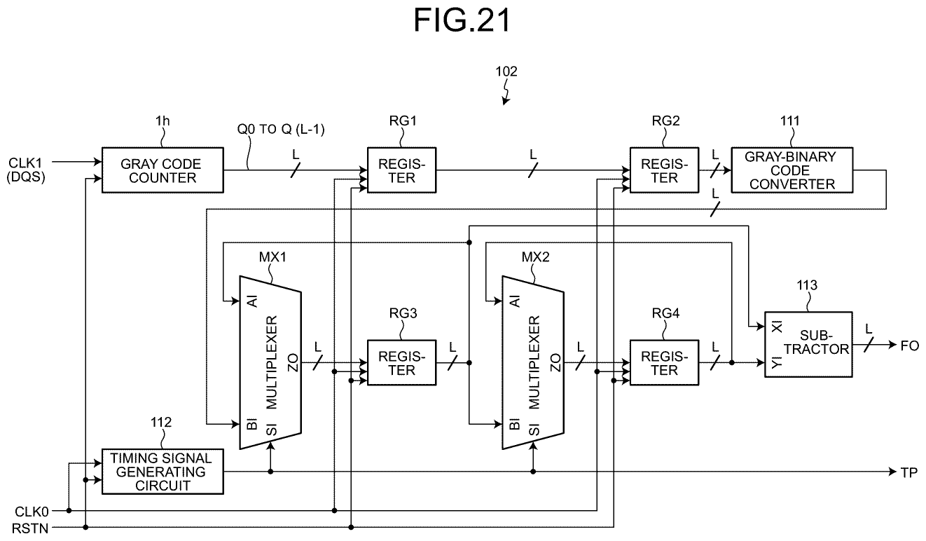

FIG. 21 is a diagram illustrating an example of a configuration of the frequency counter 102 according to the ninth embodiment.

The frequency counter 102 includes a Gray code counter 1h, four registers RG1 to RG4, a Gray-binary code converter 111, two multiplexers MX1 and MX2, a timing signal generating circuit 112, and a subtractor 113.

The reset signal RSTN is input to reset terminals of the Gray code counter 1h, the registers RG1 to RG4, and the timing signal generating circuit 112. The clock signal CLK0 is input to clock terminals of the registers RG1 to RG4 and the timing signal generating circuit 112.

The Gray code counter 1h is a semiconductor integrated circuit having a configuration similar to any one of the Gray code counter 1 of the first embodiment to the Gray code counter 1g of the eighth embodiment. The data strobe signal DQS is input as the clock signal CLK1 to a clock terminal (the clock terminal TCLK in the first embodiment) of the Gray code counter 1h. The Gray code counter 1h counts the clock signal CLK1 input thereto. The Gray code counter 1h outputs L-bit Gray code Q0 to Q(L−1) corresponding to the count value of the clock signal CLK1 from a data output terminal (the set of data output terminals TQ0 to TQ(L−1) of the first to eighth embodiments).

The data output terminal of the Gray code counter 1h is connected to a data input terminal of the register RG1. The register RG1 stores the L-bit Gray code output from the data output terminal of the Gray code counter 1h therein at the timing based on the clock signal CLK0, more specifically, at the timing of the rising edge of the clock signal CLK0.

A data output terminal of the register RG1 is connected to a data input terminal of the register RG2. A data output terminal of the register RG2 is connected to the Gray-binary code converter 111.

The Gray-binary code converter 111 converts the L-bit Gray code into L-bit binary data. As a result, L-bit data in which the count value of the clock signal CLK1 is expressed in binary digits is obtained.

The multiplexer MX1 includes two input terminals AI and BI each receiving L-bit data as input, an output terminal ZO that outputs L-bit data, and an input terminal SI to which a selection signal is input. The input terminal Al of the multiplexer MX1 is connected to an output terminal of the register RG3. The input terminal BI of the multiplexer MX1 is connected to an output terminal of the Gray-binary code converter 111.

An input terminal of the register RG3 is connected to the output terminal of the multiplexer MX1.

The multiplexer MX2 includes two input terminals Al and BI each receiving L-bit data as input, an output terminal ZO that outputs L-bit data, and an input terminal SI to which the selection signal is input. The input terminal Al of the multiplexer MX2 is connected to an output terminal of the register RG4. The input terminal BI of the multiplexer MX2 is connected to the output terminal of the register RG3. The output terminal ZO of the multiplexer MX2 is connected to an input terminal of the register RG4.

Based on the clock signal CLK0, the timing signal generating circuit 112 generates a timing pulse TP that takes the value of “1” during one clock cycle in every certain number of clock cycles (hereinafter, referred to as a count period). The timing pulse TP is input to the multiplexers MX1 and MX2 as the selection signal.

In a case where the input selection signal (namely, the timing pulse TP) is “0”, each of the multiplexers MX1 and MX2 selects input from the input terminal Al. In a case where the input selection signal (namely, the timing pulse TP) is “1”, each of the multiplexers MX1 and MX2 selects input from the input terminal BI.

The subtractor 113 includes two input terminals XI and YI each receiving L-bit data as input, and an output terminal. The input terminal XI is connected to the output terminal of the register RG3. The input terminal Y1 is connected to the output terminal of the register RG4. The subtractor 113 subtracts the L-bit data input to the input terminal YI from the L-bit data input to the input terminal XI and outputs L-bit data obtained by the subtraction as data (hereinafter, frequency data) FO corresponding to the frequency of the clock signal CLK1. The frequency data FO corresponds to the count value of the clock signal CLK1 in the count period.

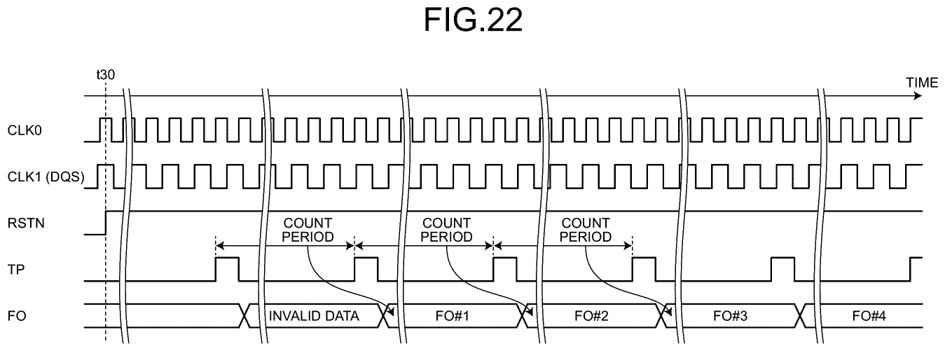

FIG. 22 is a timing chart illustrating an example of waveforms of various signals in the frequency counter 102 according to the ninth embodiment. As illustrated in the drawing, when the resetting by the reset signal RSTN is canceled (timing t30) and the timing pulse TP set to “1” during one clock cycle in every count period is input to the multiplexers MX1 and MX2, the count value of the clock signal CLK1 (namely, the data strobe signal DQS) obtained in each count period is output as the frequency data FO in a following count period.

The control circuit 103 acquires the frequency data FO as the count value by the frequency counter 102. The control circuit 103 adjusts the oscillation frequency of the oscillation circuit 101 on the basis of the frequency data FO acquired from the frequency counter 102.

In one example, in response to determining that the frequency of the clock signal CLK0 is lower than the frequency of the clock signal CLK1 on the basis of the frequency data FO acquired from the frequency counter 102, the control circuit 103 increases the oscillation frequency of the oscillation circuit 101. In response to determining that the frequency of the clock signal CLK0 is not lower than the frequency of the clock signal CLK1, the control circuit 103 does not change the oscillation frequency of the oscillation circuit 101. Note that the method for adjusting the oscillation frequency of the oscillation circuit 101 is not limited to the above.

As described above, according to the ninth embodiment, the bridge chip BC includes the Gray code counter 1h that counts the clock signal CLK1, the oscillation circuit 101 that generates the clock signal CLK0, and the register RG1 that stores the Gray code output from the Gray code counter 1h therein at timing based on the clock signal CLK0.

Note that the Gray code counter 1h according to the ninth embodiment is applicable not only to the bridge chip BC but also to an optional semiconductor device that operates based on a clock signal different from a clock signal to be counted by the Gray code counter 1h.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit generating an L-bit Gray code (where L is an integer larger than or equal to 3) corresponding to a count value of a first clock signal, the semiconductor integrated circuit comprising:
a first flip-flop including a clock terminal to which the first clock signal is configured to be input, a D terminal, and a Q terminal configured to output a first signal;
a second flip-flop including a clock terminal to which the first clock signal is configured to be input, a D terminal to which the first signal output from the Q terminal of the first flip-flop is configured to be input, and a Q terminal;
a first inverter configured to
perform inversion calculation on a second signal output from the Q terminal of the second flip-flop, and
output a signal to be input to the D terminal of the first flip-flop;
a second inverter configured to perform inversion calculation on the first signal;
(L−1) adders, each configured to calculate a different bit of the Gray code by an addition operation based on a carry signal input to the corresponding adder;
a circuit block configured to
generate a carry signal to be input to a first adder of the (L−1) adders, on a basis of a calculation of a logical product of the first signal and the second signal, and
generate carry signals to be individually input to a second adder to an (L−1)th adder of the (L−1) adders, on a basis of the second signal and a signal output from the second inverter;
a first terminal configured to output the second signal; and
(L−1) second terminals, each configured to output a third signal output from a corresponding one of the (L−1) adders.

2. The semiconductor integrated circuit according to claim 1, wherein
the (L−1) adders each includes
a third flip-flop including a clock terminal to which the first clock signal is configured to be input, a D terminal, and a Q terminal configured to output the third signal, and
an exclusive OR circuit configured to
calculate an exclusive OR of a carry signal input thereto and the third signal output from the Q terminal of the third flip-flop, and
output a signal to be input to the D terminal of the third flip-flop, and
each of the (L−1) second terminals is configured to output the third signal from the Q terminal of the third flip-flop of a corresponding one of the (L−1) adders.

3. The semiconductor integrated circuit according to claim 2, further comprising:
an exclusive NOR circuit configured to
calculate an exclusive OR of the third signal output from the Q terminal of the third flip-flop in the (L−1)th adder and the third signal output from the Q terminal of the third flip-flop in an (L−2)th adder of the (L−1) adders, and
perform inversion calculation on a signal obtained by the calculation of the exclusive OR; and
a first AND circuit configured to calculate a logical product of a fourth signal output from the exclusive NOR circuit and a fifth signal output from the circuit block as a carry signal for the (L−1)th adder,
wherein the exclusive OR circuit in the (L−1)th adder is configured to calculate an exclusive OR of a signal output from the first AND circuit and the third signal output from the Q terminal of the third flip-flop in the (L−1)th adder.

4. The semiconductor integrated circuit according to claim 3, further comprising:
a third inverter configured to perform inversion calculation on the fourth signal;
a second AND circuit configured to calculate a logical product of a signal output from the third inverter and the fifth signal; and
a third terminal configured to output a signal output from the second AND circuit.

5. A semiconductor integrated circuit generating an L-bit Gray code (where L is an integer larger than or equal to 3) corresponding to a count value of a first clock signal, the semiconductor integrated circuit comprising:
a first flip-flop including a clock terminal to which the first clock signal is configured to be input, a D terminal, and a Q terminal configured to output a first signal;
a first terminal to which a selection signal is input;
a first exclusive NOR circuit configured to
calculate an exclusive OR of the first signal output from the Q terminal of the first flip-flop and the selection signal, and
perform inversion calculation on a signal obtained by the calculation of the exclusive OR;
a second flip-flop including a clock terminal to which the first clock signal is configured to be input, a D terminal to which a signal output from the first exclusive NOR circuit is configured to be input, and a Q terminal;
a first exclusive OR circuit configured to
calculate an exclusive OR of a second signal output from the Q terminal of the second flip-flop and the selection signal, and
output a signal to be input to the D terminal of the first flip-flop;
a second exclusive NOR circuit configured to
calculate an exclusive OR of the first signal and the selection signal, and
perform inversion calculation on a signal obtained by the calculation of the exclusive OR by the second exclusive NOR circuit;
a second exclusive OR circuit configured to calculate an exclusive OR of the first signal and the selection signal;
(L−1) adders, each configured to calculate a different bit of the Gray code by an addition operation based on a carry signal input to the corresponding adder;
a circuit block configured to
generate a carry signal to be input to a first adder of the (L−1) adders, on a basis of a calculation of a logical product of a signal output from the second exclusive NOR circuit and the second signal, and
generate carry signals to be individually input to a second adder to an (L−1)th adder of the (L−1) adders, on a basis of a signal output from the second exclusive OR circuit and the second signal;
a second terminal configured to output the second signal; and
(L−1) third terminals, each configured to output a third signal output from a corresponding one of the (L−1) adders.

6. The semiconductor integrated circuit according to claim 5, wherein
the (L−1) adders each includes
a third flip-flop including a clock terminal to which the first clock signal is configured to be input, a D terminal, and a Q terminal configured to output the third signal; and
a third exclusive OR circuit configured to
calculate an exclusive OR of a carry signal input thereto and the third signal output from the Q terminal of the third flip-flop, and
output a signal to be input to the D terminal of the third flip-flop, and
each of the (L−1) third terminals is configured to output the third signal from the Q terminal of the third flip-flop of a corresponding one of the (L−1) adders.

7. The semiconductor integrated circuit according to claim 6, further comprising:
a fourth exclusive OR circuit configured to calculate an exclusive OR of the third signal output from the Q terminal of the third flip-flop in the (L−1)th adder and the third signal output from the Q terminal of the third flip-flop in an (L−2)th adder of the (L−1) adders;
a fifth exclusive OR circuit configured to calculate an exclusive OR of a signal output from the fourth exclusive OR circuit and the selection signal; and
a first AND circuit configured to calculate a logical product of a fourth signal output from the fifth exclusive OR circuit and a fifth signal output from the circuit block as a carry signal for the (L−1)th adder,
wherein the third exclusive OR circuit in the (L−1)th adder is configured to calculate an exclusive OR of a signal output from the first AND circuit and the third signal output from the Q terminal of the third flip-flop in the (L−1)th adder.

8. The semiconductor integrated circuit according to claim 7, further comprising:
an inverter is configured to perform inversion calculation on the fourth signal;
a second AND circuit is configured to calculate a logical product of a signal output from the inverter and the fifth signal; and
a fourth terminal configured to output a signal output from the second AND circuit.

9. A semiconductor integrated circuit generating an L-bit Gray code (where L is an integer larger than or equal to 3) corresponding to a count value of a first clock signal, the semiconductor integrated circuit comprising:
a first flip-flop including a clock terminal to which the first clock signal is configured to be input, a D terminal, and a Q terminal;
a second flip-flop including a clock terminal to which the first clock signal is configured to be input, a D terminal, and a Q terminal configured to output a first signal to be input to the D terminal of the first flip-flop;
a first inverter configured to
perform inversion calculation on a second signal output from the Q terminal of the first flip-flop, and
output a third signal to be input to the D terminal of the second flip-flop, the third signal being obtained by the inversion calculation on the second signal;
(L−1) adders, each configured to calculate a different bit of the Gray code by an addition operation based on a carry signal input to the corresponding adder;
a circuit block configured to
generate a carry signal to be input to a first adder of the (L−1) adders, on a basis of a calculation of a logical product of the first signal and the third signal, and
generate carry signals to be individually input to a second adder to an (L−1)th adder of the (L−1) adders, on a basis of a the first signal and the second signal;
a first terminal configured to output the first signal; and
(L−1) second terminals, each configured to output a fourth signal output from a corresponding one of the (L−1) adders, wherein
the (L−1) adders each includes
a third flip-flop including a clock terminal to which the first clock signal is input, a D terminal, and a Q terminal configured to output the fourth signal, and
a first exclusive OR circuit configured to
calculate an exclusive OR of a carry signal input thereto and the fourth signal output from a Q terminal of the third flip-flop, and
input a signal obtained by the calculation of the exclusive OR to the D terminal of the third flip-flop,
each of the (L−1) second terminals is configured to output the fourth signal from the Q terminal of the third flip-flop of a corresponding one of the (L−1) adders, and wherein,
the semiconductor integrated circuit further comprises:
a second exclusive OR circuit configured to calculate an exclusive OR of the fourth signal output from the Q terminal of the third flip-flop in the (L−1)th adder and the fourth signal output from the Q terminal of the third flip-flop in an (L−2)th adder of the (L−1) adders; and
a first AND circuit configured to calculate a logical product of a fifth signal output from the second exclusive OR circuit and a sixth signal output from the circuit block as a carry signal for the (L−1)th adder, and
the first exclusive OR circuit in the (L−1)th adder is configured to calculate an exclusive OR of a signal output from the first AND circuit and the fourth signal output from the Q terminal of the third flip-flop in the (L−1)th adder.

10. The semiconductor integrated circuit according to claim 9, further comprising:
a second inverter configured to perform inversion calculation on the fifth signal;
a second AND circuit configured to calculate a logical product of a signal output from the second inverter and the sixth signal; and
a third terminal configured to output a signal output from the second AND circuit.

11. A semiconductor device including the semiconductor integrated circuit according to claim 1, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

12. A semiconductor device including the semiconductor integrated circuit according to claim 2, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

13. A semiconductor device including the semiconductor integrated circuit according to claim 3, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

14. A semiconductor device including the semiconductor integrated circuit according to claim 4, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

15. A semiconductor device including the semiconductor integrated circuit according to claim 5, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

16. A semiconductor device including the semiconductor integrated circuit according to claim 6, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

17. A semiconductor device including the semiconductor integrated circuit according to claim 7, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

18. A semiconductor device including the semiconductor integrated circuit according to claim 8, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

19. A semiconductor device including the semiconductor integrated circuit according to claim 9, the semiconductor device comprising:
an oscillation circuit configured to generate a second clock signal; and
a register configured to store the Gray code output from the first terminal and the (L−1) second terminals of the semiconductor integrated circuit at timing based on the second clock signal.

20. A semiconductor device including the semiconductor integrated circuit according to claim 10, the semiconductor device comprising:
an oscillation circuit configured to generate a second clock signal; and
a register configured to store the Gray code output from the first terminal and the (L−1) second terminals of the semiconductor integrated circuit at timing based on the second clock signal.
